(19) United States
(12) Patent Application Publication
(10) Pub. No.: US 2025/0233390 A1
(43) Pub. Date: Jul. 17, 2025

(54) SEMICONDUCTOR LASER, SEMICONDUCTOR LASER DEVICE, AND SEMICONDUCTOR LASER PRODUCTION METHOD

(71) Applicant: Mitsubishi Electric Corporation, Tokyo (JP)

(72) Inventors: Hiroaki MAEHARA, Tokyo (JP); Satoshi TAIRA, Tokyo (JP); Ayumi FUCHIDA, Tokyo (JP); Ryoko SUZUKI, Tokyo (JP); Ryosuke MIYAGOSHI, Tokyo (JP)

(73) Assignee: Mitsubishi Electric Corporation, Tokyo (JP)

(21) Appl. No.: 18/849,078

(22) PCT Filed: May 23, 2022
(86) PCT No.: PCT/JP2022/021063

§ 371 Date: Sep. 20, 2024

(51) Int. Cl. H01S 5/223; H01S 5/024; H01S 5/22

(52) U.S. Cl. CPC H01S 5/223; H01S 5/02469; H01S 5/2202; H01S 5/2223

(57) ABSTRACT

A semiconductor laser comprises a ridge formed on an n-type semiconductor substrate, a buried layer buried so as to cover both sides in an x-direction perpendicular to a y-direction, which is the direction in which the ridge extends. In a positive side of a z-direction that is the direction in which the ridge protrudes and the positive side of the buried layer in the z-direction, provided are a p-type second cladding layer, a p-type contact layer, a surface-side electrode that is connected to the p-type contact layer, and a semi-insulating layer that is formed on an outer edge separated from the ridge in the x-direction. The semi-insulating layer or the front surface-side electrode is formed on sides toward x-direction ends of the semiconductor laser on the positive side in the z-direction.

### TECHNICAL FIELD

The present application relates to a semiconductor laser, a semiconductor laser device, and a semiconductor laser production method.

### BACKGROUND ART

A semiconductor laser is widely used as a light source for optical communication, and is highly required to have a small size, high-speed operation, high efficiency, and low power consumption. Patent Document 1 discloses a semiconductor laser having a buried heterostructure. The semiconductor laser of Patent Document 1 is provided with a ridge including an n-type semiconductor substrate, an n-type cladding layer, an active layer, and a p-type cladding layer, a buried region where the ridge is buried, a pair of trench grooves formed in the buried region, the p-type cladding layer and a contact layer that are stacked on the ridge and the buried region, an anode electrode connected to the contact layer, a cathode electrode formed on a rear surface of the n-type semiconductor substrate, and an insulating film covering the contact layer and the trench grooves except for a region directly above the ridge. The insulating film made of silicon dioxide (SiO₂) or the like allows a current to be efficiently injected from the anode electrode to the active layer.

Further, in order to improve the characteristics of the semiconductor laser, it is important to reduce the resistance of an injection current path. The resistance of the injection current path is referred to as an injection resistance as appropriate. In particular, in a semiconductor laser for high-output use, the operating current is large, the heat generation due to the injection resistance is large, and the deterioration of the characteristics is remarkable. Therefore, it is quite important to efficiently dissipate the heat generated during the operation.

In order to efficiently dissipate heat generated during operation of the semiconductor laser, so-called junction-down mounting may be performed in which the semiconductor laser is mounted such that a pn junction of the semiconductor laser faces a heat sink. Patent Document 2 discloses a semiconductor laser device in which a semiconductor laser is mounted on a heat sink by the junction-down mounting.

In the semiconductor laser device of Patent Document 2, in order to efficiently dissipate heat generated during the operation of the semiconductor laser to the heat sink, a cladding layer, a contact layer, and an electrode metal are sequentially stacked on a waveguide layer including an active layer, a recess (trench) penetrating the contact layer and reaching the vicinity of the active layer is formed in the cladding layer, and a heat transfer material is filled between the recess (trench) and the heat sink. In the semiconductor laser device of Patent Document 2, the heat transfer material having a high thermal conductivity is disposed in the vicinity of the active layer being a heat generation source to increase the heat conductivity of a heat dissipation path to the heat sink, thereby improving heat dissipation performance.

### CITATION LIST

### Patent Document

Patent Document 1: Japanese Patent Application Laid-Open No. 2011-216680 (FIG. 1)
Patent Document 2: Japanese Patent Application Laid-Open No. 2001-94210 (FIG. 1, FIG. 8)

### SUMMARY OF INVENTION

### Problems to be Solved by Invention

In the semiconductor laser device of Patent Document 2, a thick cladding layer is formed above the waveguide layer including the active layer, and the resistance of the injection current path is larger than that of the semiconductor laser of Patent Document 1. To reduce the resistance of the injection current path and suppress a leakage current that does not contribute to laser oscillation, a semiconductor laser with a buried structure such as the semiconductor laser of the Patent Document 1 are typically used. When the semiconductor laser of Patent Document 1 is mounted on the heat sink by the junction-down mounting, the thermal resistance of the heat dissipation path to the heat sink is increased by the insulating film with low thermal conductivity because there is an insulating film covering the contact layer and the trench grooves except for the region directly above the ridge including the active layer.

In the case where the semiconductor laser of Patent Document 1 is mounted on the heat sink by the junction-down mounting, the thermal resistance of the heat dissipation path increases, and a problem arises in that the heat dissipation of the semiconductor laser is not sufficient.

The technology disclosed in the specification of the present application aims to achieve excellent heat dissipation while the leakage current that does not contribute to laser oscillation is suppressed when the junction-down mounting is performed on the heat sink.

### Means for Solving the Problems

A semiconductor laser as an example disclosed in the present specification includes a ridge formed on an n-type semiconductor substrate, and a buried layer buried so as to cover both sides opposite to each other in a direction perpendicular to an extension direction of the ridge, and the semiconductor laser is mounted from a surface on a side where the ridge protrudes. A z-direction is a direction to which the ridge protrudes from a front surface side of the n-type semiconductor substrate, a y-direction is an extension direction in which the ridge extends, and an x-direction is a direction perpendicular to the z-direction and the y-direction. The ridge includes an n-type cladding layer, an active layer, and a p-type first cladding layer that are sequentially formed from a side of the n-type semiconductor substrate. The buried layer includes a p-type first buried layer in contact with a side surface of the ridge on a negative side in the x-direction and a side surface of the ridge on a positive side in the x-direction, a second buried layer, and an n-type third buried layer. The semiconductor laser includes a p-type second cladding layer and a p-type contact layer that are sequentially formed from the side of the n-type semiconductor substrate on the positive side of the ridge in the z-direction and on the positive side of the n-type third buried layer in the z-direction, a front surface-side electrode connected to the p-type contact layer, and a semi-insulating layer formed in outer edges separated in the x-direction from a ridge portion including the ridge and the p-type first buried layer in contact with the two side surfaces of the ridge, and the semi-insulating layer or the front surface-side electrode is formed on the positive side in the z-direction at sides toward x-direction ends in the semiconductor laser.

### Effect of Invention

An example of the semiconductor laser disclosed in the specification of the present application includes the semi-insulating layer on the outer edge which is separated in the x-direction from the ridge portion having the active layer and is on the side opposite to the n-type semiconductor substrate. Therefore, when the semiconductor laser is mounted from the front surface-side electrode side, it is possible to achieve excellent heat dissipation while suppressing a leakage current that does not contribute to laser oscillation.

### BRIEF DESCRIPTION OF DRAWINGS

FIG. 1 is a diagram showing a cross-sectional structure of a first semiconductor laser according to Embodiment 1.

FIG. 2 is a diagram showing a cross-sectional structure of a semiconductor laser device according to Embodiment 1.

FIG. 3 is a diagram showing a cross-sectional structure of a second semiconductor laser according to Embodiment 1.

FIG. 4 is a diagram showing a method of manufacturing the semiconductor laser of FIG. 1.

FIG. 5 is a diagram showing a method of manufacturing the semiconductor laser of FIG. 1.

FIG. 6 is a diagram showing a method of manufacturing the semiconductor laser of FIG. 1.

FIG. 7 is a diagram showing a method of manufacturing the semiconductor laser of FIG. 1.

FIG. 8 is a diagram showing a method of manufacturing the semiconductor laser of FIG. 1.

FIG. 9 is a diagram showing a method of manufacturing the semiconductor laser of FIG. 1.

FIG. 10 is a diagram showing a cross-sectional structure of a semiconductor laser of a comparative example.

FIG. 11 is a diagram showing a cross-sectional structure of a semiconductor laser device of the comparative example.

FIG. 12 is a diagram showing a cross-sectional structure of a semiconductor laser according to Embodiment 2.

FIG. 13 is a diagram showing a cross-sectional structure of a semiconductor laser device according to Embodiment 2.

FIG. 14 is a diagram showing a width of a protruding portion of the semiconductor laser of FIG. 12.

FIG. 15 is a diagram showing a method of manufacturing the semiconductor laser of FIG. 12.

FIG. 16 is a diagram showing a method of manufacturing the semiconductor laser of FIG. 12.

FIG. 17 is a diagram showing a method of manufacturing the semiconductor laser of FIG. 12.

FIG. 18 is a diagram showing a method of manufacturing the semiconductor laser of FIG. 12.

FIG. 19 is a diagram showing a method of manufacturing the semiconductor laser of FIG. 12.

FIG. 20 is a diagram showing a cross-sectional structure of a semiconductor laser according to Embodiment 3.

FIG. 21 is a diagram showing a cross-sectional structure of a semiconductor laser device according to Embodiment 3.

FIG. 22 is a diagram showing a method of manufacturing the semiconductor laser of FIG. 20.

FIG. 23 is a diagram showing a method of manufacturing the semiconductor laser of FIG. 20.

FIG. 24 is a diagram showing a method of manufacturing the semiconductor laser of FIG. 20.

FIG. 25 is a diagram showing a cross-sectional structure of a first semiconductor laser according to Embodiment 4.

FIG. 26 is a diagram showing a cross-sectional structure of a first semiconductor laser device according to Embodiment 4.

FIG. 27 is a diagram showing a cross-sectional structure of a second semiconductor laser according to Embodiment 4.

FIG. 28 is a diagram showing a cross-sectional structure of a second semiconductor laser device according to Embodiment 4.

FIG. 29 is a diagram showing a cross-sectional structure of a third semiconductor laser according to Embodiment 4.

FIG. 30 is a diagram showing a width of a protruding portion in the semiconductor laser according to Embodiment 4.

FIG. 31 is a diagram showing a method of manufacturing the semiconductor laser of FIG. 25.

FIG. 32 is a diagram showing a method of manufacturing the semiconductor laser of FIG. 25.

FIG. 33 is a diagram showing a method of manufacturing the semiconductor laser of FIG. 25.

FIG. 34 is a diagram showing a method of manufacturing the semiconductor laser of FIG. 25.

FIG. 35 is a diagram showing a cross-sectional structure of a first semiconductor laser according to Embodiment 5.

FIG. 36 is a diagram showing a cross-sectional structure of a first semiconductor laser device according to Embodiment 5.

FIG. 37 is a diagram showing a cross-sectional structure of a second semiconductor laser according to Embodiment 5.

FIG. 38 is a diagram showing a cross-sectional structure of a second semiconductor laser device according to Embodiment 5.

FIG. 39 is a diagram showing a cross-sectional structure of a third semiconductor laser according to Embodiment 5.

FIG. 40 is a diagram showing a method of manufacturing the semiconductor laser of FIG. 35.

### MODES FOR CARRYING OUT INVENTION

### Embodiment 1

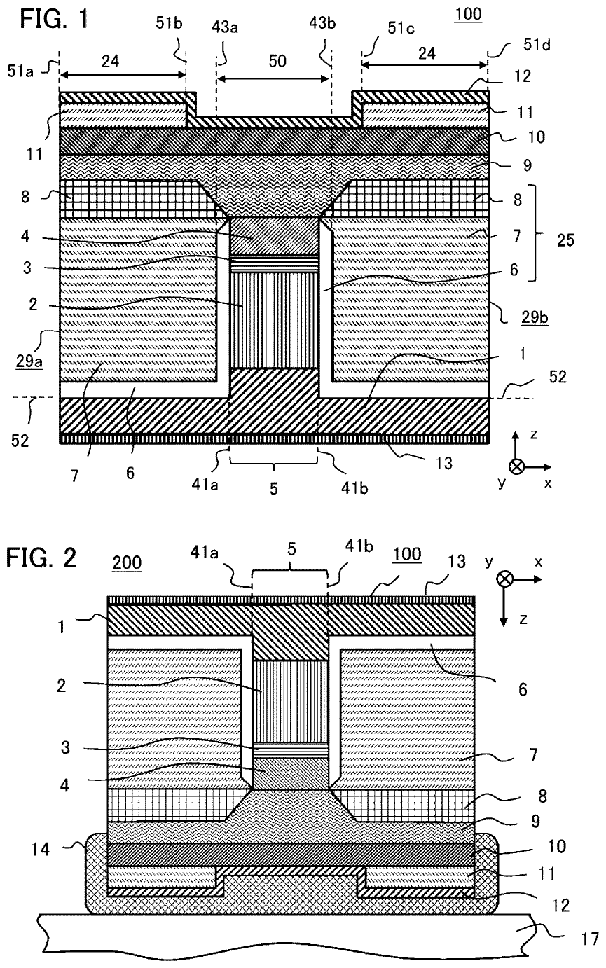

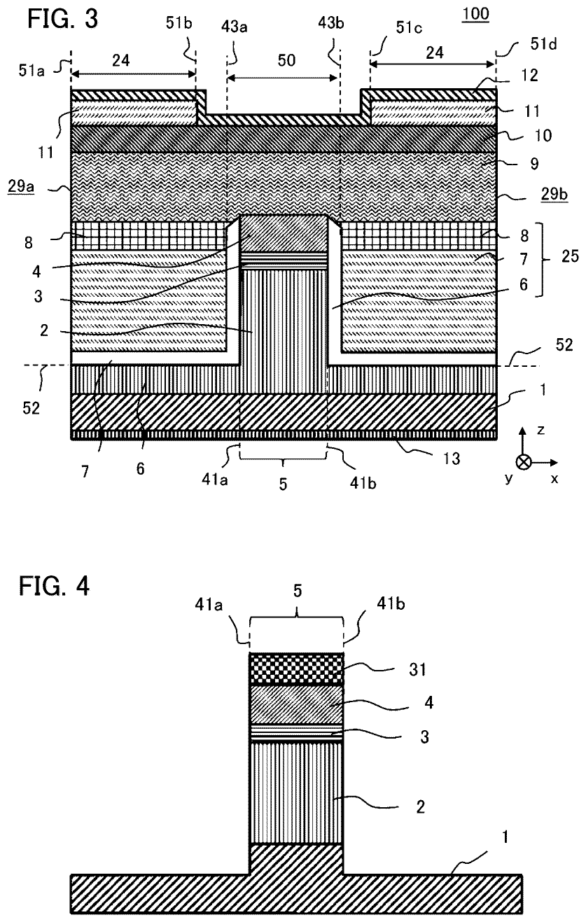

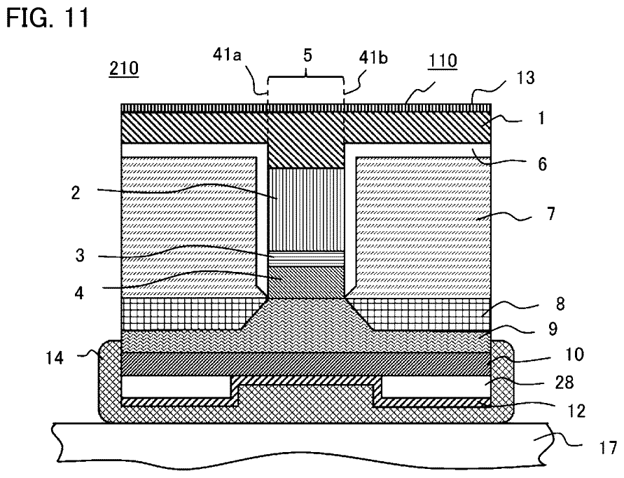

FIG. 1 is a diagram showing a cross-sectional structure of a first semiconductor laser according to Embodiment 1, and FIG. 2 is a diagram showing a cross-sectional structure of a semiconductor laser device according to Embodiment 1. FIG. 3 is a diagram showing a cross-sectional structure of a second semiconductor laser according to Embodiment 1. FIG. 4 to FIG. 9 are diagrams showing a method of manufacturing the semiconductor laser of FIG. 1. FIG. 10 is a diagram showing a cross-sectional structure of a semiconductor laser of a comparative example, and FIG. 11 is a diagram showing a cross-sectional structure of a semiconductor laser device of the comparative example. A semiconductor laser 100 of Embodiment 1 includes a ridge 5 formed on an n-type semiconductor substrate 1, which is an n-type InP substrate, and a buried layer 25 buried so as to cover both sides of the ridge 5 opposite to each other in a direction perpendicular to an extension direction of the ridge 5. A direction in which the ridge 5 protrudes from the front surface side of the n-type semiconductor substrate 1 is defined as a z-direction, the extension direction in which the ridge 5 extends is defined as a y-direction, and a direction perpendicular to the z-direction and the y-direction is defined as an x-direction. In the semiconductor laser 100 shown in FIG. 1, the ridge 5 protrudes from the front side of the n-type semiconductor substrate 1 to the positive side in the z-direction, the end on the positive side in the x-direction indicated by a broken line 51a is an x-direction end 29b, and the end on the negative side in the x-direction indicated by a broken line 51d is an x-direction end 29a. The ridge 5 is formed between a broken line 41a and a broken line 41b, and a ridge portion 50 is formed between a broken line 43a and a broken line 43b. Note that the positive side in the z-direction is referred to as a front surface side, and the negative side in the z-direction is referred to as a rear surface side, as appropriate.

The semiconductor laser 100 is provided with the ridge 5 including an n-type cladding layer 2, an active layer 3, and a p-type first cladding layer 4 that are sequentially formed from a side of the n-type semiconductor substrate, and the buried layer 25 including a p-type first buried layer 6 in contact with the positive side surface in the x-direction and the negative side surface in the x-direction in the ridge 5, a second buried layer 7, and an n-type third buried layer 8, and provided with a p-type second cladding layer 9, a p-type contact layer 10, which are formed on the positive side of the ridge 5 in the z-direction and on the positive side of the n-type third buried layer 8 in the z-direction sequentially from the side of the n-type semiconductor substrate 1, an anode electrode 12 being a front surface-side electrode connected to the p-type contact layer 10, and a semi-insulating layer 11 formed in outer edges separated in the x-direction from the ridge portion 50 including the ridge 5 and the p-type first buried layer 6 in contact with two side surfaces of the ridge 5, and also provided with a cathode electrode 13 being a rear side electrode formed on the rear surface of the n-type semiconductor substrate 1. The semi-insulating layer 11 and the anode 12 are formed on the positive side in the z-direction at sides toward the x-direction ends 29a and 29b of the semiconductor laser 100. On the side of the x-direction end 29a of the semiconductor laser 100, the semi-insulating layer 11 is formed in an end region 24 from the broken line 51a to a broken line 51b. Similarly, on the side of the x-direction end 29b of the semiconductor laser 100, the semi-insulating layer 11 is formed in the end region 24 from a broken line 51c to the broken line 51d.

The semiconductor laser device 200 of Embodiment 1 includes the semiconductor laser 100 and a heat sink 17, and the positive side in the z-direction where the anode electrode 12 of the semiconductor laser 100 is formed is connected to the heat sink 17 by a connection member 14 such as gold-tin solder. FIG. 2 shows a cross section of the semiconductor laser device 200 mounted on the heat sink 17 by a junction-down mounting. The semiconductor laser 100 is mounted on the heat sink 17 by the junction-down mounting from the surface side from which the ridge 5 protrudes, that is, from the positive side in the z-direction.

The n-type semiconductor substrate 1 is the n-type InP substrate which is an InP substrate doped with, for example, sulfur (S). The n-type cladding layer 2 is, for example, an n-type InP cladding layer doped with sulfur. The active layer 3 includes a multiple quantum well of an AlGaInAS-based or InGaASP-based material. The p-type first cladding layer 4 is, for example, a p-type InP cladding layer doped with zinc (Zn). The ridge 5 has a stripe shape extending in the y-direction.

The ridge 5 is formed by etching the semiconductor layers of the n-type cladding layer 2, the active layer 3, and the p-type first cladding layer 4, which are sequentially formed on the n-type semiconductor substrate 1, to a position lower than the active layer 3, that is, to a position lower than the negative side of the active layer 3 in the z-direction. The first semiconductor laser 100 shown in FIG. 1 is an example in which a ridge etching position 52 reaches the n-type semiconductor substrate 1, and a second semiconductor laser 100 shown in FIG. 3 is an example in which the ridge etching position 52 is disposed in the n-type cladding layer 2. The ridge 5 is buried up to a position higher than the active layer 3, that is, a position higher than an active layer surface position 44 (refer to FIG. 6) on the positive side of the active layer 3 in the z-direction by the p-type first buried layer 6 in contact with the side surface on the positive side in the x-direction and the side surface on the negative side in the x-direction, the second buried layer 7, and the n-type third buried layer 8. The p-type first buried layer 6 is, for example, a p-type InP buried layer doped with zinc, the second buried layer 7 is a semi-insulating InP buried layer doped with iron (Fe) being a semi-insulating material, and the n-type third buried layer 8 is, for example, an n-type InP buried layer doped with sulfur.

The first semiconductor laser 100 shown in FIG. 1 is an example in which the second buried layer 7 is formed up to a position on the positive side of the ridge 5 in the z-direction, and the second semiconductor laser 100 shown in FIG. 3 is an example in which the second buried layer 7 is formed up to the active layer surface position 44. The second buried layer 7 may be a semi-insulating InP buried layer doped with a material such as titanium (Ti), cobalt (Co), or rubidium (Ru). Further, the p-type first buried layer 6 and the second buried layer 7 may be constituted by a combination with other semiconductor layers each having a different impurity concentration or conductivity type. The n-type third buried layer 8 is formed on the surface of the second buried layer 7, and the p-type second cladding layer 9 is formed on the n-type third buried layer 8 and the ridge 5 on the positive side in the z-direction. The p-type contact layer 10 is formed on the p-type second cladding layer 9 on the positive side in the z-direction, and the semi-insulating layer 11 is formed on the p-type contact layer 10 in the end regions 24 on the positive side in the z-direction. The anode electrode 12 is formed so as to cover the surface of the semi-insulating layer 11 and the surface of the p-type contact layer 10 from which the semi-insulating layer 11 is removed, and the cathode electrode 13 is formed on the rear surface side of the n-type semiconductor substrate 1. An opening of the semi-insulating layer 11 is disposed on the positive side in the z-direction in a region of the p-type contact layer 10 where the ridge portion 50 is encompassed. The region where the opening of the semi-insulating layer 11 is disposed is a region through which a current flows from the anode 12 to the ridge 5 via the p-type contact layer 10 and the p-type second cladding layer 9. The first semiconductor laser 100 shown in FIG. 1 is an example in which the n-type third buried layer 8 is formed at a position farther from the n-type semiconductor substrate 1 than the positive side of the ridge 5 in the z-direction, and the second semiconductor laser 100 shown in FIG. 3 is an example in which the n-type third buried layer 8 is formed closer to the n-type semiconductor substrate 1 than the positive side of the ridge 5 in the z-direction. FIG. 1 and FIG. 3 show an example in which the anode electrode 12 covers the entire positive side of the semiconductor laser 100 in the z-direction.

The p-type second cladding layer 9 is, for example, the p-type InP cladding layer doped with zinc, and the p-type contact layer 10 is, for example, a p-type InGaAS contact layer doped with zinc. The semi-insulating layer 11 is, for example, an InP semi-insulating layer doped with iron. The semi-insulating layer 11 may be a semi-insulating InP layer doped with a material such as titanium, cobalt, rubidium, etc. The material of the anode electrode 12 and the cathode electrode 13 is a metal such as gold (Au), germanium (Ge), zinc, platinum (Pt), or titanium. In the case where the connection member 14 is gold-tin solder when the semiconductor laser 100 is mounted by the junction-down mounting, a barrier metal such as platinum may be interposed between the p-type contact layer 10 and the anode electrode 12 in order to prevent gold from diffusing into the p-type contact layer 10 and a semiconductor layer closer to the n-type semiconductor substrate 1 than the p-type contact layer 10.

Next, a method of manufacturing the semiconductor laser 100 of Embodiment 1 will be described using an example shown in FIG. 4 to FIG. 9. Although FIG. 4 to FIG. 9 show a method of manufacturing the first semiconductor laser 100, the description will be made also to include a method of manufacturing the second semiconductor laser 100. FIG. 4 shows a ridge forming step of forming the ridge 5. In the ridge forming step, the n-type cladding layer 2, the active layer 3, and the p-type first cladding layer 4 are sequentially formed on the n-type semiconductor substrate 1, and a first mask 31 made of SiO₂, SiN, or the like is formed with a width of the ridge 5 in the x-direction. Next, using the first mask 31, by the etching down to a position lower than the negative side of the active layer 3 in the z-direction, which is on the side of the n-type semiconductor substrate 1, the ridge 5 that includes the n-type cladding layer 2, the active layer 3, and the p-type first cladding layer 4 and in which the side surface on the positive side in the x-direction and the side surface on the negative side in the x-direction are exposed is formed. The ridge etching position 52 for forming the ridge 5 is a position lower than the negative side of the active layer 3 in the z-direction.

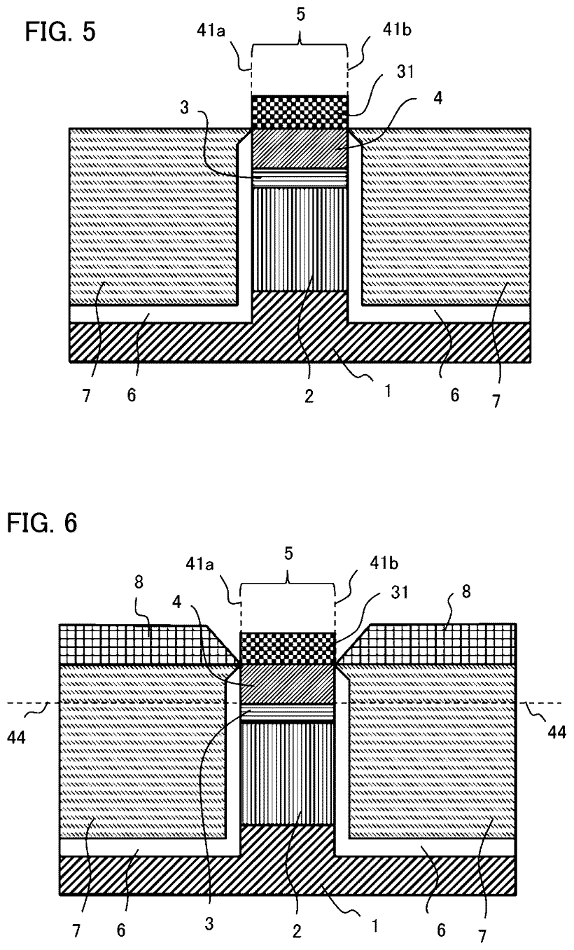

FIG. 5 and FIG. 6 show a burying step of burying the ridge 5 with the buried layer 25. In the burying step, the p-type first buried layer 6 is formed on the side surface on the positive side in the x-direction and the side surface on the negative side in the x-direction, that is, both side surfaces of the ridge 5, by using the first mask 31, and the ridge 5 is buried to a position higher than the active layer surface position 44 that is a positive side position of the active layer 3 in the z-direction by the second buried layer 7 and the n-type third buried layer 8 that are sequentially formed. The first semiconductor laser 100 shown in FIG. 1 and the second semiconductor laser 100 shown in FIG. 3 are examples in which the second buried layer 7 is formed up to the position higher than the active layer surface position 44.

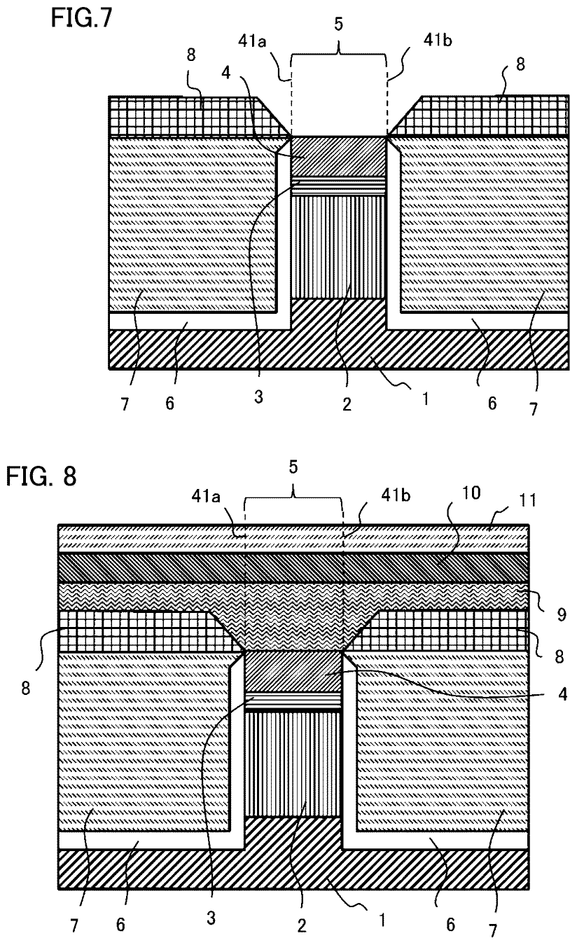

FIG. 7 and FIG. 8 show a stacking step of stacking semiconductor layers on the surfaces of the ridge 5 and the buried layer 25. As shown in FIG. 7, the first mask 31 is removed by using buffered hydrofluoric acid or hydrofluoric acid as a preprocessing of the stacking step. Thereafter, in the stacking step, the p-type second cladding layer 9, the p-type contact layer 10, and the semi-insulating layer 11 are sequentially formed on the positive side of the ridge 5 in the z-direction and on the positive side of the n-type third buried layer 8 in the z-direction.

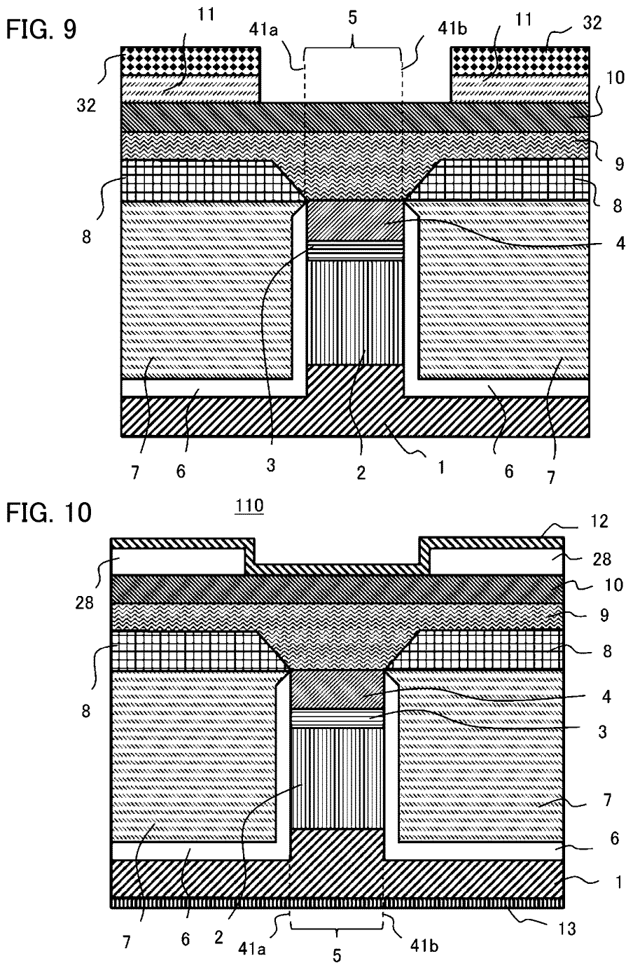

FIG. 9 shows a contact layer exposing step of exposing the p-type contact layer 10. In the contact layer exposing step, a resist mask 32 is formed in which a region in an x-direction encompassing the ridge portion 50 including the ridge 5 and the p-type first buried layer 6 in contact with two side surfaces of the ridge 5 is opened, and then the semi-insulating layer 11 is selectively etched by hydrochloric acid using the resist mask 32 to expose the p-type contact layer 10. Thereafter, the resist mask 32 is removed.

Next, as shown in FIG. 1 and FIG. 3, a front surface-side electrode forming step of forming the anode electrode 12 as the front surface-side electrode on the exposed p-type contact layer 10, on the positive side of the semi-insulating layer 11 in the z-direction, and on the side surfaces of the semi-insulating layer 11 on the side of the ridge portion 50 is performed, and a rear surface-side electrode forming step of forming the cathode electrode 13 as the rear surface-side electrode on the rear surface side of the n-type semiconductor substrate 1, i.e., on the negative side in the z-direction is performed. The semiconductor laser 100 of Embodiment 1 is manufactured by the above-described steps.

FIG. 10 and FIG. 11 show a semiconductor laser 110 and a semiconductor laser device 210 as the comparative example. The semiconductor laser 110 of the comparative example is different from the first semiconductor laser 100 of Embodiment 1 in that an insulating film 28 of SiO₂ is formed on the p-type contact layer 10 instead of the semi-insulating layer 11.

An operation of the semiconductor laser 100 and the semiconductor laser device 200 of Embodiment 1 will be described. In the operation, a forward bias is applied between the anode electrode 12 and the cathode electrode 13 of the semiconductor laser 100. In the semiconductor laser device 200 of Embodiment 1, the forward bias is applied between the anode electrode 12 and the cathode electrode 13 of the semiconductor laser 100 via the heat sink 17. When the forward bias is applied between the anode electrode 12 and the cathode electrode 13, a current is injected from the anode electrode 12 into the p-type contact layer 10 of a semi-insulating layer opening region that encompasses the ridge portion 50 and in which the semi-insulating layer 11 is removed. The semi-insulating layer opening region is a current injection region. The injected current is constricted to the region of the ridge 5 having the stripe shape by the second buried layer 7 and the n-type third buried layer 8, and is input to the ridge 5. Laser light having a wavelength corresponding to the bandgap energy of the semiconductor layer constituting the active layer 3 is generated by the current injected into the active layer 3, and the laser light is emitted to the outside of the semiconductor laser 100. The laser light is emitted in the y-direction in which the ridge 5 extends.

The main heat source of the semiconductor laser 100 is the active layer 3. The heat generated in the active layer 3 is conducted to the surrounding semiconductor layers and spreads to the outside of the active layer 3. In the semiconductor laser 110 and the semiconductor laser device 210 of the comparative example, the heat generated in the active layer 3 is conducted from the active layer 3 to the surrounding semiconductor layers, that is, the p-type first buried layer 6, the second buried layer 7, the n-type third buried layer 8, the p-type second cladding layer 9, and the p-type contact layer 10. In the semiconductor laser 110 and the semiconductor laser device 210 of the comparative example, the current injection region is an insulating film opening region where the insulating film 28 is removed. In the current injection region, the heat is conducted from the p-type contact layer 10 to the anode electrode 12. However, in the outer regions outside the current injection region where the insulating film 28 exists, the heat is conducted from the p-type contact layer 10 to the anode electrode 12 through the insulating film 28. Thereafter, the heat is dissipated from the anode electrode 12 to the heat sink 17 through the connection member 14. In the semiconductor laser 110 of the comparative example, the p-type contact layer 10 is covered with the insulating film 28 except for the current injection region encompassing the ridge 5 including the active layer 3 in order to suppress a leakage current to regions other than the active layer 3. The thermal conductance of SiO₂ used as the insulating film 28 is 1.38 W/(m·K). As compared with InP, which has a thermal conductance of 70 W/(m·K), SiO₂ has a poor thermal conductance. Therefore, in the semiconductor laser device in which the semiconductor laser 110 of the comparative example is mounted by the junction-down mounting, that is, the semiconductor laser device 210 of the comparative example, the heat dissipation from surface regions of the insulating film 28, that is, from the above-described outer regions, is not sufficient, and the high-temperature characteristics thereof deteriorate. In the semiconductor laser device 210 of the comparative example in which the semiconductor laser 110 of the comparative example is mounted by the junction-down mounting, the heat dissipation is not sufficient because the thermal resistance of the heat dissipation path is large.

In contrast, in the semiconductor laser 100 of Embodiment 1, the semi-insulating layer 11 of InP instead of the insulating film 28 is interposed between the p-type contact layer 10 and the anode electrode 12 outside the current injection region, that is, in the end regions 24 on the positive side and the negative side of the current injection region in the x-direction, and thus the thermal resistance of the heat dissipation path in the end regions 24 is lower than that of the comparative example, thereby improving the heat dissipation as compared with the comparative example. Since the semi-insulating layer 11 is doped with, for example, iron and has the semi-insulating property, it is possible to suppress a leakage current to other portions except for the active layer 3 at the time of current injection. Since the semiconductor laser 100 of Embodiment 1 includes the semi-insulating layer 11 in the end regions 24 on the positive side of the p-type contact layer 10 in the z-direction, it is possible to achieve excellent heat dissipation and improve high-temperature characteristics while the leakage current to those other than the active layer 3, which does not contribute to laser oscillation, is suppressed.

Note that the material of the semi-insulating layer 11 is not limited to InP, but may be made of a material whose thermal conductivity is 10 times greater than that of SiO₂. Even in this case, the semiconductor laser 100 of Embodiment 1 can reduce the thermal resistance of the heat dissipation path as compared with the comparative example, and can achieve excellent heat dissipation while the leakage current that does not contribute to laser oscillation is suppressed.

As described above, the semiconductor laser 100 of Embodiment 1 includes the ridge 5 formed on the n-type semiconductor substrate 1 and the buried layer 25 buried so as to cover both sides of the ridge opposite to each other in the direction perpendicular to the extension direction of the ridge 5, and is a semiconductor laser mounted from the surface on the side where the ridge 5 protrudes. A direction in which the ridge 5 protrudes from the front surface side of the n-type semiconductor substrate 1 is defined as the z-direction, an extension direction in which the ridge 5 extends is defined as the y-direction, and a direction perpendicular to the z-direction and the y-direction is defined as the x-direction. The ridge 5 includes the n-type cladding layer 2, the active layer 3, and the p-type first cladding layer 4, which are sequentially formed from the side of the n-type semiconductor substrate 1. The buried layer 25 includes the p-type first buried layer 6 that is in contact with the side surface of the ridge 5 on the positive side in the x-direction and the side surface of the ridge 5 on the negative side in the x-direction, the second buried layer 7, and the n-type third buried layer 8. The semiconductor laser 100 includes the p-type second cladding layer 9, the p-type contact layer 10, which are sequentially formed on the positive side of the ridge 5 in the z-direction and on the positive side of the n-type third buried layer 8 in the z-direction in this order from the side of the n-type semiconductor substrate 1, the front surface-side electrode (anode electrode 12) connected to the p-type contact layer 10, and the semi-insulating layer 11, the semi-insulating layer 11 being formed on the outer edges separated in the x-direction from the ridge portion 50 including the ridge 5 and the p-type first buried layer 6 in contact with two side surfaces of the ridge 5. The semi-insulating layer 11 or the front surface-side electrode (anode electrode 12) is formed on the positive side in the z-direction at the sides toward the x-direction ends (x-direction ends 29a and 29b) in the semiconductor laser 100. With this configuration, the semiconductor laser 100 of Embodiment 1 includes the semi-insulating layer 11 that is separated in the x-direction from the ridge portion 50 having the active layer 3 and is at the outer edges on the side opposite to the n-type semiconductor substrate 1. Therefore, when the semiconductor laser 100 is mounted from the side of the front surface-side electrode (anode electrode 12), excellent heat dissipation can be achieved while the leakage current that does not contribute to the laser oscillation is suppressed.

The semiconductor laser device 200 of Embodiment 1 includes the semiconductor laser 100 of Embodiment 1 and the heat sink 17, and the positive side in the z-direction on which the front surface-side electrode (anode electrode 12) of the semiconductor laser 100 is formed is connected to the heat sink 17 with the connection member 14. With this configuration, the semiconductor laser device 200 of Embodiment 1 includes the semi-insulating layer 11 on the outer edges separated in the x-direction from the ridge portion 50 having the active layer 3 and on the side opposite to the n-type semiconductor substrate 1, and the positive side in the z-direction on which the front surface-side electrode (anode electrode 12) is formed is connected to the heat sink 17 with the connecting member. Therefore, in the case of the mounting from the front surface-side electrode (anode electrode 12), excellent heat dissipation can be achieved while the leakage current that does not contribute to the laser oscillation is suppressed.

The semiconductor laser production method of Embodiment 1 is a semiconductor laser production method of manufacturing the semiconductor laser 100 including the ridge 5 formed on the n-type semiconductor substrate 1 and the buried layer 25 buried so as to cover both sides of the ridge opposite to each other in the direction perpendicular to the extension direction of the ridge 5. The semiconductor laser production method of Embodiment 1 includes the ridge forming step, the burying step, the stacking step, the contact layer exposing step, and the front surface-side electrode forming step, which will be described below. In the ridge forming step, the n-type cladding layer 2, the active layer 3, and the p-type first cladding layer 4 are sequentially formed on the n-type semiconductor substrate 1, and then by the etching down to a position lower than the negative side of the active layer 3 in the z-direction, which is on the side of the n-type semiconductor substrate 1, the ridge 5 that includes the n-type cladding layer 2, the active layer 3, and the p-type first cladding layer 4 and in which the side surface on the positive side in the x-direction and the side surface on the negative side in the x-direction are exposed is formed. In the burying step, the p-type first buried layer 6 is formed on the side surface on the positive side in the x-direction and the side surface on the negative side in the x-direction in the ridge 5, and the ridge 5 is buried by the second buried layer 7 and the n-type third buried layer 8 that are sequentially formed to a position higher than the active layer surface position 44 that is a positive side position of the active layer 3 in the z-direction. In the stacking step, the p-type second cladding layer 9, the p-type contact layer 10, and the semi-insulating layer 11 are sequentially formed on the positive side of the ridge 5 in the z-direction and on the positive side of the n-type third buried layer 8 in the z-direction. In the contact layer exposing step, the p-type contact layer 10 is exposed by etching the semi-insulating layer 11 in a region in the x-direction encompassing the ridge portion 50 including the ridge 5 and the p-type first buried layer 6 in contact with the two side surfaces of the ridge 5. In the front surface-side electrode forming step, the front surface-side electrode (anode electrode 12) is formed on the exposed p-type contact layer 10, on the positive side of the semi-insulating layer 11 in the z-direction, and on the side surfaces of the semi-insulating layer 11 on the side of the ridge portion 50. With this configuration, the semiconductor laser production method of Embodiment 1 can manufacture the semiconductor laser 100 including the semi-insulating layer 11 that is separated in the x-direction from the ridge portion 50 having the active layer 3 and is at the outer edges on the side opposite to the n-type semiconductor substrate 1, so that excellent heat dissipation can be achieved while the leakage current not contributing to laser oscillation is suppressed when the semiconductor laser 100 is mounted from the side of the front surface-side electrode (anode electrode 12).

### Embodiment 2

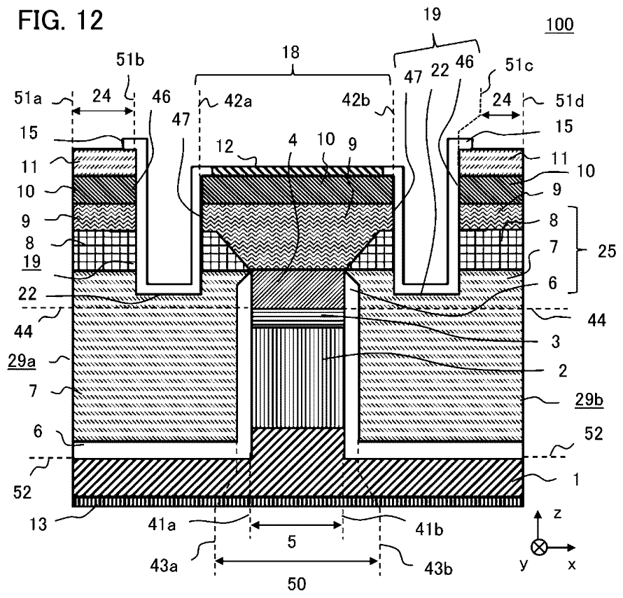

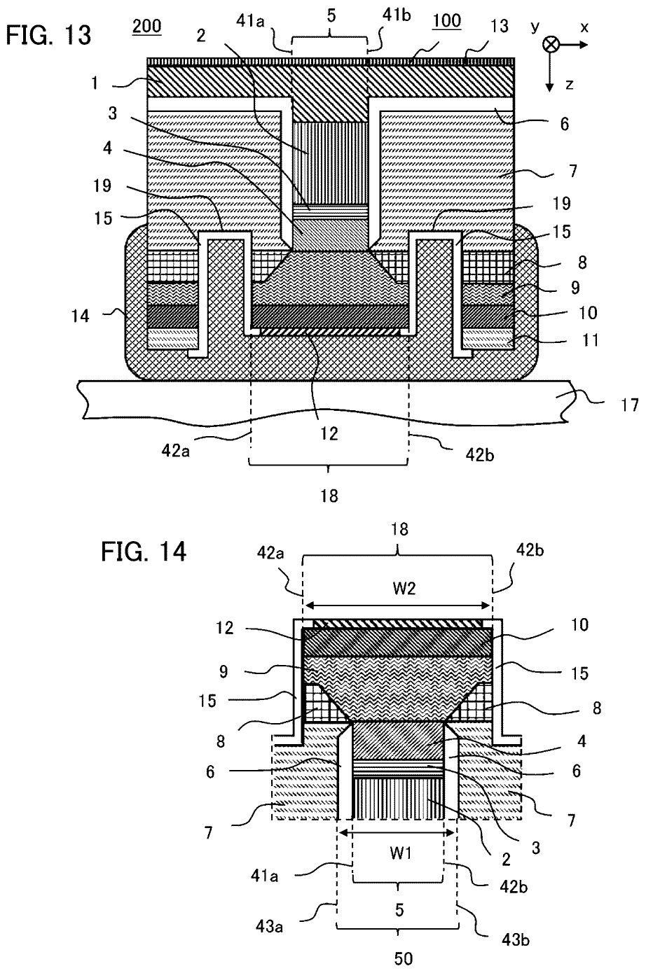

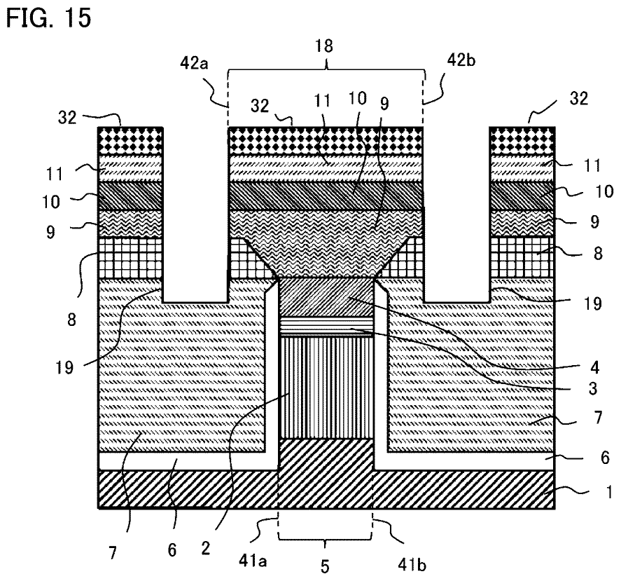

FIG. 12 is a diagram showing a cross-sectional structure of a semiconductor laser device according to Embodiment 2, and FIG. 13 is a diagram showing a cross-sectional structure of a semiconductor laser device according to Embodiment 2. FIG. 14 is a diagram showing a width of a protruding portion in the semiconductor laser of FIG. 12. FIG. 15 to FIG. 19 are diagrams showing a method of manufacturing the semiconductor laser of FIG. 12. The semiconductor laser 100 of Embodiment 2 is different from the semiconductor laser 100 of Embodiment 1 in that the semiconductor laser 100 of Embodiment 2 includes two trenches 19 formed to extend in the y-direction between outer sides of the ridge portion 50 in the x-direction and the x-direction ends 29a and 29b. Differences from the semiconductor laser 100 and the semiconductor laser device 200 of Embodiment 1 will be mainly described.

Similarly to the semiconductor laser 100 of Embodiment 1, the semiconductor laser 100 of Embodiment 2 includes the ridge 5 formed on the n-type semiconductor substrate 1 and the buried layer 25 buried so as to cover both sides of the ridge opposite to each other in the direction perpendicular to the extension direction of the ridge 5, the p-type second cladding layer 9 formed on the positive side of the ridge 5 in the z-direction and on the positive side of the n-type third buried layer 8 in the z-direction, the p-type contact layer 10, the semi-insulating layer 11 formed on the outer edges separated in the x-direction from the ridge portion 50, the anode electrode 12, and the cathode electrode 13. The semiconductor laser 100 of Embodiment 2 further includes two trenches 19 formed to extend in the y-direction between the outer sides of the ridge portion 50 in the x-direction and the x-direction ends 29a and 29b, and an insulating film 15 formed on the inner surfaces of the trenches 19. The material of the insulating film 15 is SiO₂, SiN, or another material having an insulating property. FIG. 12 and FIG. 13 show an example in which the x-direction end 29a side of the semi-insulating layer 11 on the negative side in the x-direction and the x-direction end 29b side of the semi-insulating layer 11 on the positive side in the x-direction are exposed. However, the surface of the semi-insulating layer 11 may be covered with the anode electrode 12 or a metal not connected to the anode electrode 12.

The trenches 19 penetrate the p-type contact layer 10, the p-type second cladding layer 9, and the n-type third buried layer 8, and the bottom portions 22 of the trenches 19 are at the same position as the active layer surface position 44 that is a positive side of the active layer 3 in the z-direction in the second buried layer 7, or the position of the bottom portions 22 of the trenches 19 is more distant from the n-type semiconductor substrate 1 than the active layer surface position 44 in the second buried layer 7. That is, the bottom portions 22 of the trenches 19 should be located between the active layer surface position 44 and the positive side of the second buried layer 7 in the z-direction. The anode electrode 12 is connected to the p-type contact layer 10 in the protruding portion 18 formed between the two trenches 19. The protruding portion 18 is formed to extend in the y-direction in a range in the x-direction from a broken line 42a to a broken line 42b. Since the trenches 19 correspond to mesa grooves, the protruding portion 18 can also be referred to as a mesa stripe.

Side surfaces of the trenches 19 in the x-direction on the side separated from the protruding portion 18 are trench first side surfaces 46, and side surfaces of the trenches 19 in the x-direction on the sides closer to the protruding portion 18 than the trench first side surfaces 46 are trench second side surfaces 47. On the x-direction end 29b side, the trench 19 is formed between the broken line 42b and a broken line 51c, and the end region 24 is formed between the broken line 51c and the broken line 51d. On the x-direction end 29a side, the trench 19 is formed between the broken line 42a and the broken line 51b, and the end region 24 is formed between the broken line 51b and the broken line 51a. The semi-insulating layer 11 is formed on the positive side of the p-type contact layer 10 in the z-direction from the trench first side surfaces 46 of the trenches 19 to the x-direction ends (x-direction ends 29a and 29b) opposite to the protruding portion 18 of the semiconductor laser 100, and is not covered with the anode electrode on the sides toward x-direction ends of the semiconductor laser 100. That is, the semi-insulating layer 11 is formed on the positive side of the p-type contact layer 10 in the z-direction in the end region 24 on the side of the x-direction end 29b, and is formed on the positive side of the p-type contact layer 10 in the z-direction in the end region 24 on the side of the x-direction end 29b.

FIG. 13 shows an example of the semiconductor laser device 200 in which the semiconductor laser 100 of Embodiment 2 is mounted on the heat sink 17 by the junction-down mounting while the connection member 14 is filled in the trenches 19 and the connection member 14 in a position on the negative side in the z-direction covers a part of the second buried layer 7 at the x-direction ends 29a and 29b. A protruding portion width W2, which is the width of the protruding portion 18 in the x-direction, is larger than a ridge width W1, which is the width of the ridge portion 50 in the x-direction.

Next, a method of manufacturing the semiconductor laser 100 of Embodiment 2 will be described with reference to the above-described FIG. 4 to FIG. 8 and an example shown in FIG. 15 to FIG. 19. The ridge forming step, the burying step, and the stacking step shown in FIG. 4 to FIG. 8 are the same as those of Embodiment 1. After the stacking step shown in FIG. 8, a trench forming step shown in FIG. 15 is performed. In the semiconductor layers formed up to the semi-insulating layer 11, two trenches 19 are formed on both sides of the ridge portion 50 in the x-direction using a resist mask 32 such that the bottom portions 22 are located at a position lower than the n-type third buried layer 8 and higher than the active layer 3. More specifically, in the trench forming step, the trenches 19 are formed to penetrate the semi-insulating layer 11, the p-type contact layer 10, the p-type second cladding layer 9, and the n-type third buried layer 8 at two outer edges separated from the ridge portion 50 on the positive side and the negative side in the x-direction, and the trenches 19 are formed such that the position of the bottom portions 22 in the z-direction is the same as the active layer surface position 44 of the active layer 3 in the second buried layer 7 or the bottom portions 22 are positioned on the positive side from the active layer surface position 44.

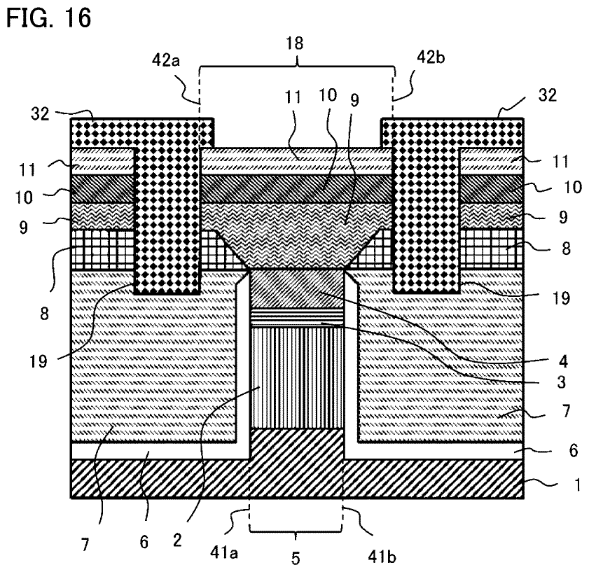

Next, the contact layer exposing step of exposing the p-type contact layer 10 by etching the semi-insulating layer 11 of the protruding portion 18 formed between the two trenches 19, and an insulating film forming step of forming the insulating film 15 on both side surfaces in the x-direction and the bottom portion 22 of each trench 19 are performed. As shown in FIG. 16, a resist mask 32 is formed so as to form an opening at the center of the protruding portion 18 in the x-direction, and the semi-insulating layer 11 of the protruding portion 18 is selectively etched with hydrochloric acid. FIG. 16 shows an example in which the width of the opening of the resist mask 32 in the x-direction is smaller than that of the protruding portion 18.

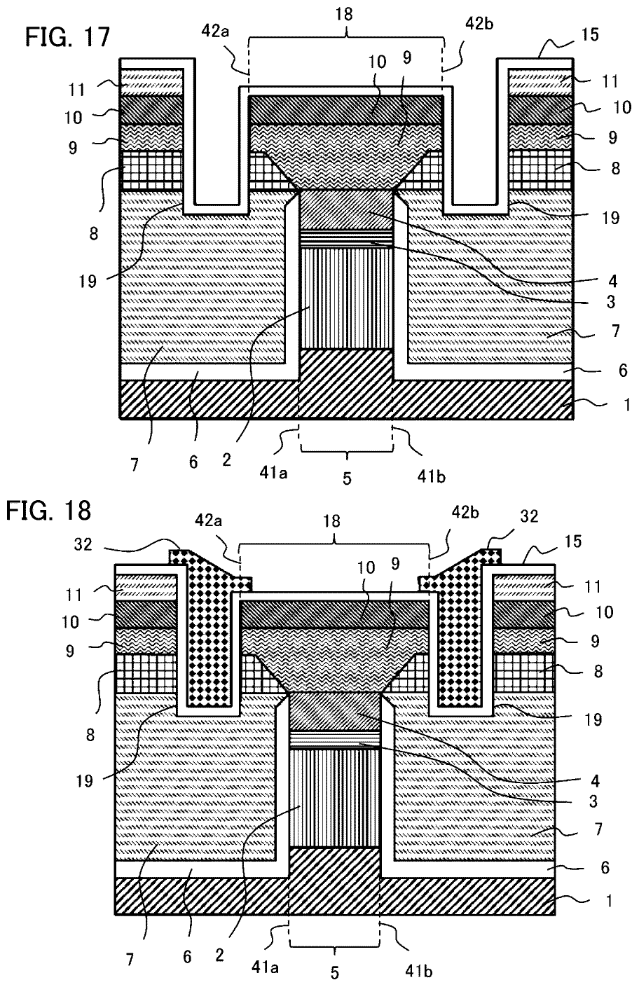

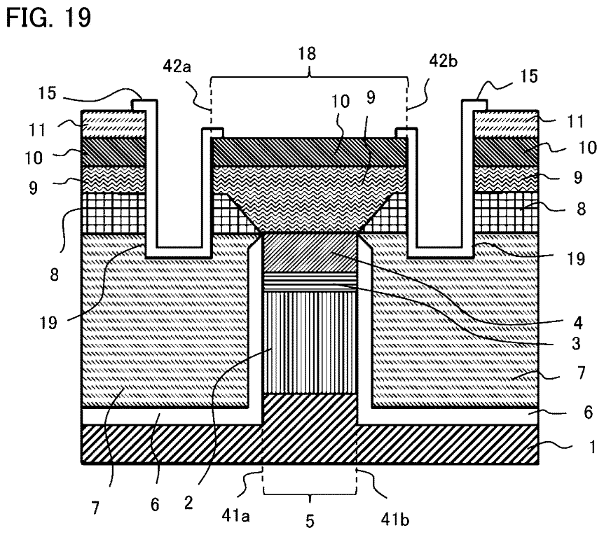

Next, the insulating film 15 having a final shape, that is, the insulating film 15 having the shape shown in FIG. 19, is formed. After the resist mask 32 is removed as shown in FIG. 17, the insulating film 15 is formed on the exposed surface of the semiconductor layers and the inner surfaces of the trenches 19. Next, a resist mask 32 is formed so as to cover the trenches 19 as shown in FIG. 18, and the shape of the insulating film 15 is processed by etching as shown in FIG. 19. Thereafter, the resist mask 32 is removed. In FIG. 18, an example in which the width of the resist mask 32 in the x-direction is larger than the width of the trench 19 in the x-direction is shown. In the example shown in FIG. 19, the insulating film forming step of forming the insulating film 15 in the final shape by etching the insulating film 15 and the contact layer exposing step of exposing the p-type contact layer 10 by etching the insulating film 15 on the protruding portion 18 are simultaneously performed. In the contact layer exposing step of exposing the p-type contact layer 10, a step shown in FIG. 16 and a step shown in FIG. 19 are performed. As the insulating film forming step of forming the insulating film 15 on both side surfaces of the trenches 19 in the x-direction and the bottom portions 22, the steps shown in FIG. 17 to FIG. 19 are performed.

Thereafter, as shown in FIG. 12, the front surface-side electrode forming step of forming the anode electrode 12 so as to cover the p-type contact layer 10 where the insulating film 15 of the protruding portion 18 is not formed in the insulating film forming step, and the rear surface-side electrode forming step of forming the cathode electrode 13 on the rear surface side of the n-type semiconductor substrate 1, that is, on the negative side in the z-direction, are performed. The anode electrode 12 is patterned by using a resist mask. The semiconductor laser 100 of Embodiment 2 is manufactured by the above-described steps.

In the semiconductor laser device 200 of Embodiment 2 in which the semiconductor laser 100 of Embodiment 2 is mounted by the junction-down mounting, heat generated in the active layer 3 is conducted from the active layer 3 to the surrounding semiconductor layers, that is, the p-type first buried layer 6, the second buried layer 7, the n-type third buried layer 8, the p-type second cladding layer 9, and the p-type contact layer 10. In the protruding portion 18, the heat from the active layer 3 is dissipated from the anode electrode 12 to the heat sink 17 through the connection member 14. In the end regions 24, the heat from the active layer 3 is conducted to the semi-insulating layer 11, and is dissipated from the semi-insulating layer 11 to the heat sink 17 via the connection member 14.

In the semiconductor laser 100 of Embodiment 2, as in the semiconductor laser 100 of Embodiment 1, the semi-insulating layer 11 of InP covers the p-type contact layer 10 in the end regions 24 on the positive and negative sides in the x-direction on the sides of the x-direction ends 29b, 29a and the insulating film 15 formed on the inner surfaces of the trenches 19 is thinner than the insulating film 28 of the semiconductor laser 110 of the comparative example shown in FIG. 10, so that the thermal resistance of the heat dissipation path in the end regions 24 is lower than that of the comparative example, and the heat dissipation property can be improved in the same manner as that of the semiconductor laser 100 of Embodiment 1 as compared with the comparative example. Since the semi-insulating layer 11 has a semi-insulating property, it is possible to suppress a leakage current to those other than the active layer 3 at the time of the current injection. Since the semiconductor laser 100 of Embodiment 2 includes the semi-insulating layer 11 in the end regions 24 on the positive side of the p-type contact layer 10 in the z-direction as in the semiconductor laser 100 of Embodiment 1, excellent heat dissipation can be achieved and high-temperature characteristics can be improved while the leakage current to those other than the active layer 3, which does not contribute to laser oscillation, is suppressed.

In the semiconductor laser 100 of Embodiment 2, as in the semiconductor laser 100 of Embodiment 1, the buried layer 25 functioning as a current blocking layer is provided on both sides of the active layer 3 in order to improve the efficiency of current injection into the active layer 3. The buried layer 25 has a structure in which the semi-insulating second buried layer 7 doped with iron or the like is interposed between the p-type first buried layer 6 and the n-type third buried layer 8. Since the buried layer 25 on the sides of the x-direction ends 29a and 29b has a structure similar to that of a capacitor in which a dielectric is interposed, the buried layer 25 has a parasitic capacitance. In order to achieve a high-speed operation of the semiconductor laser 100, it is effective to reduce the parasitic capacitance of the buried layer 25. In the semiconductor laser 100 of Embodiment 2, the protruding portion 18 is formed so as to encompass both sides of the ridge portion 50 in the x-direction, and the n-type third buried layer 8 of the buried layer 25 is divided by the trenches 19, whereby the area of the n-type third buried layer 8 on the side of the second buried layer 7 can be made smaller than that in the semiconductor laser 100 of Embodiment 1, and thus the area of the n-type third buried layer 8 on the side of the second buried layer 7 also in the vicinity of the active layer 3 can be made small. In the vicinity of the active layer 3 where the distance between the p-type first buried layer 6 and the n-type third buried layer 8 in the buried layer 25 is small, the parasitic capacitance is larger than that on the sides of the x-direction ends 29a and 29b. In the semiconductor laser 100 of Embodiment 2, since the area of the n-type third buried layer 8 in the vicinity of the active layer 3 is smaller than that of the semiconductor laser 100 of Embodiment 1, the parasitic capacitance can be reduced more than that of the semiconductor laser 100 of Embodiment 1. That is, the semiconductor laser 100 of Embodiment 2 can achieve a higher-speed operation than the semiconductor laser 100 of Embodiment 1.

As described above, the semiconductor laser 100 of Embodiment 2 includes the ridge 5 formed on the n-type semiconductor substrate 1 and the buried layer 25 buried so as to cover both sides of the ridge opposite to each other in the direction perpendicular to the extension direction of the ridge 5, and is a semiconductor laser mounted from the surface on the side where the ridge 5 protrudes. The z-direction, the y-direction, and the x-direction are as described above. The ridge 5 includes the n-type cladding layer 2, the active layer 3, and the p-type first cladding layer 4, which are sequentially formed from the side of the n-type semiconductor substrate 1. The buried layer 25 includes the p-type first buried layer 6 that is in contact with the side surface of the ridge 5 on the positive side in the x-direction and the side surface of the ridge 5 on the negative side in the x-direction, the second buried layer 7, and the n-type third buried layer 8. The semiconductor laser 100 includes the p-type second cladding layer 9, the p-type contact layer 10, which are sequentially formed on the positive side of the ridge 5 in the z-direction and on the positive side of the n-type third buried layer 8 in the z-direction in this order from the side of the n-type semiconductor substrate 1, the front surface-side electrode (anode electrode 12) connected to the p-type contact layer 10, and the semi-insulating layer 11, the semi-insulating layer 11 being formed on the outer edges separated in the x-direction from the ridge portion 50 including the ridge 5 and the p-type first buried layer 6 in contact with two side surfaces of the ridge 5. The semi-insulating layer 11 is formed on the positive side in the z-direction at the sides toward the x-direction ends (x-direction ends 29a and 29b) in the semiconductor laser 100. Between the side surface of the ridge portion 50 on the positive side in the x-direction and the end on the positive side in the x-direction in the semiconductor laser 100 (x-direction end 29b), and between the side surface of the ridge portion 50 on the negative side in the x-direction and the end on the negative side in the x-direction in the semiconductor laser 100 (x-direction end 29a), the trenches 19 are formed to extend in the y-direction. Each of the trenches 19 penetrates the p-type contact layer 10, the p-type second cladding layer 9, and the n-type third buried layer 8, and the bottom portions 22 of the trenches 19 are at the same position as the active layer surface position 44 that is a positive side position of the active layer 3 in the z-direction in the second buried layer 7 or the bottom portions 22 of the trenches 19 is more distant from the n-type semiconductor substrate 1 than the active layer surface position 44 in the second buried layer 7. The front surface-side electrode (anode electrode 12) is connected to the p-type contact layer 10 in the protruding portion 18 formed between the two trenches 19. The side surfaces of the trenches 19 in the x-direction on the side separated from the protruding portion 18 are referred to as the trench first side surfaces 46, and the side surfaces of the trenches 19 in the x-direction on the side closer to the protruding portion 18 than the trench first side surfaces 46 are referred to as the trench second side surfaces 47. The semi-insulating layer 11 is formed on the positive side of the p-type contact layer 10 in the z-direction from the trench first side surfaces 46 of the trenches 19 to the x-direction ends (x-direction ends 29a, 29b) opposite to the protruding portion 18 of the semiconductor laser 100. The insulating film 15 is provided on the inner surfaces of the trenches 19. With this configuration, the semiconductor laser 100 of Embodiment 2 includes the semi-insulating layer 11 that is separated in the x-direction from the ridge portion 50 having the active layer 3 and is at the outer edges on the side opposite to the n-type semiconductor substrate 1. Therefore, when the semiconductor laser 100 is mounted from the side of the front surface-side electrode (anode electrode 12), excellent heat dissipation can be achieved while the leakage current that does not contribute to the laser oscillation is suppressed.

In addition, the semiconductor laser production method of Embodiment 2 is a semiconductor laser production method of manufacturing the semiconductor laser 100 including the ridge 5 formed on the n-type semiconductor substrate 1 and the buried layer 25 buried so as to cover both sides of the ridge opposite to each other in the direction perpendicular to the extension direction of the ridge 5. The semiconductor laser production method of Embodiment 2 includes the ridge forming step, the burying step, the stacking step, the trench forming step, the contact layer exposing step, the insulating film forming step, and the front surface-side electrode forming step, which are described below. In the ridge forming step, the n-type cladding layer 2, the active layer 3, and the p-type first cladding layer 4 are sequentially formed on the n-type semiconductor substrate 1, and then by the etching down to a position lower than the negative side of the active layer 3 in the z-direction, which is on the side of the n-type semiconductor substrate 1, the ridge 5 that includes the n-type cladding layer 2, the active layer 3, and the p-type first cladding layer 4 and in which the side surface on the positive side in the x-direction and the side surface on the negative side in the x-direction are exposed is formed. In the burying step, the p-type first buried layer 6 is formed on the side surface on the positive side in the x-direction and the side surface on the negative side in the x-direction in the ridge 5, and the ridge 5 is buried by the second buried layer 7 and the n-type third buried layer 8 that are sequentially formed to the position higher than the active layer surface position 44 that is a positive side position of the active layer 3 in the z-direction. In the stacking step, the p-type second cladding layer 9, the p-type contact layer 10, and the semi-insulating layer 11 are sequentially formed on the positive side of the ridge 5 in the z-direction and on the positive side of the n-type third buried layer 8 in the z-direction. In the trench forming step, the trenches 19 are formed to penetrate the semi-insulating layer 11, the p-type contact layer 10, the p-type second cladding layer 9, and the n-type third buried layer 8 at the two outer edges separated on the positive side and the negative side in the x-direction from the ridge portion 50 including the ridge 5 and the p-type first buried layer 6 that is in contact with the two side surfaces of the ridge 5, and the trenches 19 are formed such that the position of the bottom portions 22 in the z-direction is the same as the active layer surface position 44 of the active layer 3 in the second buried layer 7 or the bottom portions 22 are positioned on the positive side from the active layer surface position 44. In the contact layer exposing step, the semi-insulating layer 11 formed on the protruding portion 18 between the two trenches 19 is etched to expose the p-type contact layer 10. In the insulating film forming step, the insulating film 15 is formed on both side surfaces (the trench first side surface 46 and the trench second side surface 47) in the x-direction and the bottom portion 22 of each of the trenches 19. In the front surface-side electrode forming step, the front surface-side electrode (the anode electrode 12) is formed so as to cover the p-type contact layer 10 where the insulating film 15 on the protruding portion 18 is not formed in the insulating film forming step. With this configuration, the semiconductor laser production method of Embodiment 2 can manufacture the semiconductor laser 100 including the semi-insulating layer 11 that is separated in the x-direction from the ridge portion 50 having the active layer 3 and is at the outer edges on the side opposite to the n-type semiconductor substrate 1, so that excellent heat dissipation can be achieved while the leakage current not contributing to laser oscillation is suppressed when the semiconductor laser 100 is mounted from the side of the front surface-side electrode (anode electrode 12).

### Embodiment 3

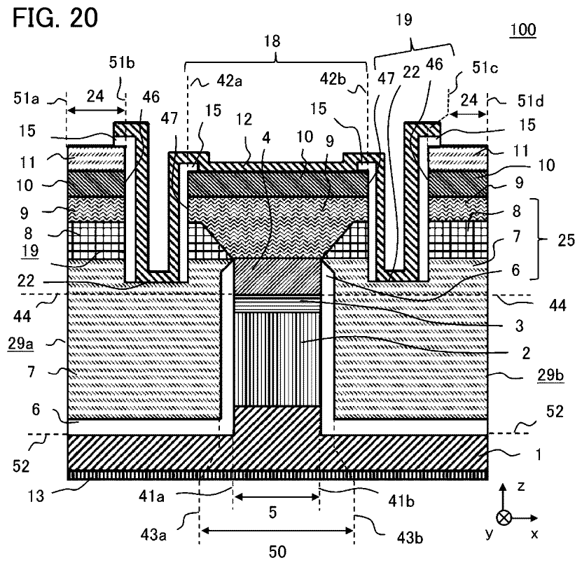

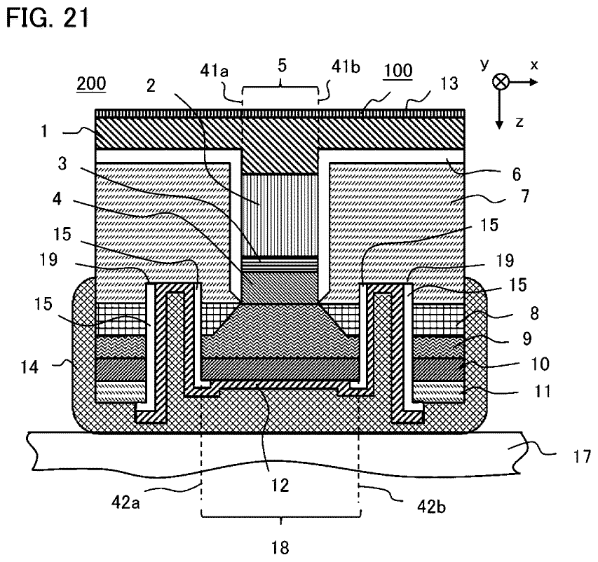

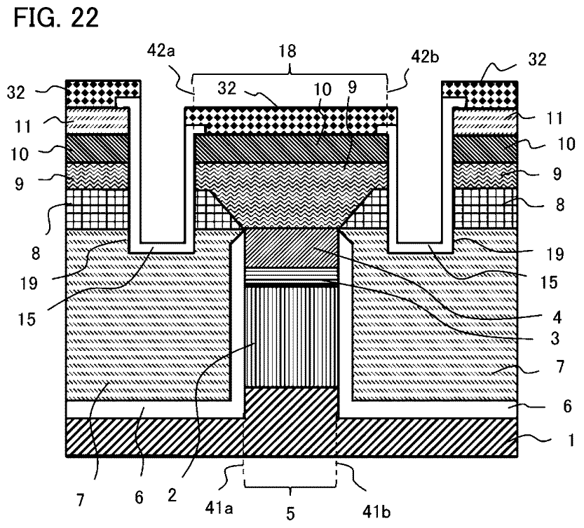

FIG. 20 is a diagram showing a cross-sectional structure of a semiconductor laser according to Embodiment 3, and FIG. 21 is a diagram showing a cross-sectional structure of a semiconductor laser device according to Embodiment 3. FIG. 22 to FIG. 24 are diagrams showing a method of manufacturing the semiconductor laser of FIG. 20. The semiconductor laser 100 of Embodiment 3 is different from the semiconductor laser 100 of Embodiment 2 in that the bottom portions 22 of the trenches 19 are not covered with the insulating film 15. Differences from the semiconductor laser 100 and the semiconductor laser device 200 of Embodiment 2 will be mainly described. FIG. 20 shows an example in which the anode electrode 12 covers the insulating film 15 on the trench first side surfaces 46 and the trench second side surfaces 47 of the trenches 19 and the bottom portions 22 of the trenches 19.

A method of manufacturing the semiconductor laser 100 of Embodiment 3 will be described with reference to the above-described FIG. 4 to FIG. 8 and FIG. 15 to FIG. 19, and an example shown in FIG. 22 to FIG. 24. The ridge forming step, the burying step, and the stacking step shown in FIG. 4 to FIG. 8 are the same as those of Embodiment 1, and the steps shown in FIG. 15 to FIG. 19 are the same as those of Embodiment 2. In the semiconductor laser 100 of Embodiment 3, a trench bottom portion exposing step that is a step of further processing the insulating film 15 shown in FIG. 19 is added. The insulating film forming step of Embodiment 3 is performed in the steps of FIG. 17 to FIG. 19 and FIG. 22 to FIG. 24. The trench bottom portion exposing step is a part of the insulating film forming step. In the contact layer exposing step of Embodiment 3, the step shown in FIG. 16 and the step shown in FIG. 19 are performed as in Embodiment 2.

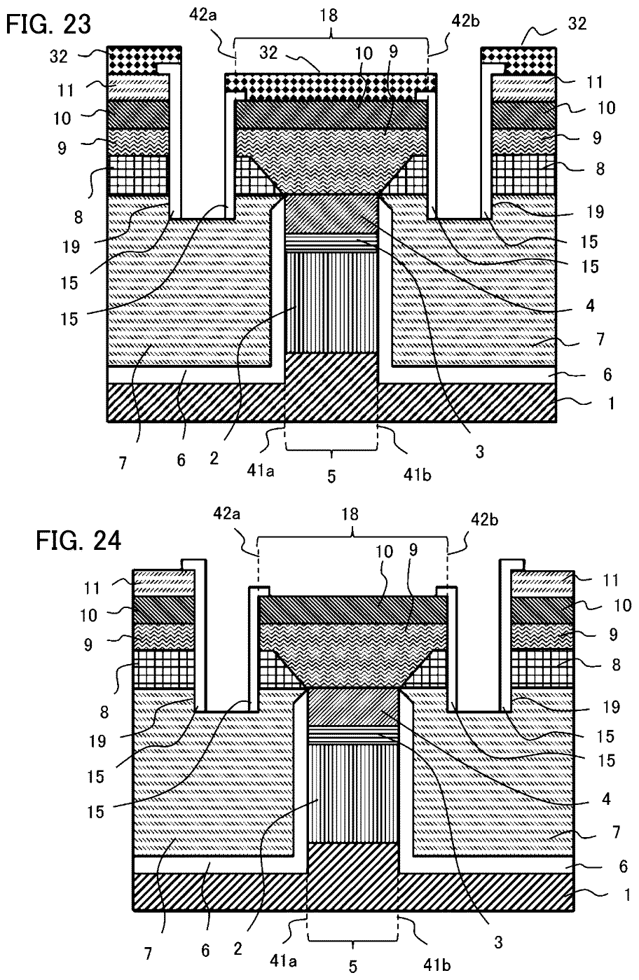

The trench bottom portion exposing step will be described. As shown in FIG. 22, a resist mask 32 is formed on the positive side of the end regions 24 in the z-direction, on the positive side of the insulating film 15 at the protruding portion 18 in the z-direction, on end portions of the insulating film disposed in the end regions 24 on the positive side in the z-direction, and on the positive side of the protruding portion 18 in the z-direction, in the semiconductor laser 100 in the middle of manufacturing shown in FIG. 19, that is, the manufacturing intermediate. FIG. 22 to FIG. 24 show an example in which there are four end portions of the insulating film. As shown in FIG. 23, using the resist mask 32, the insulating film 15 at the bottom portions 22 of the trenches 19 is etched to expose the bottom portions 22 of the trenches 19. Thereafter, as shown in FIG. 24, the resist mask 32 is removed.

Next, as shown in FIG. 20, the front surface-side electrode forming step of forming the anode electrode 12 so as to cover the p-type contact layer 10 where the insulating film 15 of the protruding portion 18 is not formed in the insulating film forming step, and the rear surface-side electrode forming step of forming the cathode electrode 13 on the rear surface side of the n-type semiconductor substrate 1, that is, on the negative side in the z-direction, are performed. The anode electrode 12 is patterned using a resist mask, and the anode electrode 12 may extend to a region other than the p-type contact layer 10 of the protruding portion 18. As described above, FIG. 20 shows an example in which the anode electrode 12 covers the insulating film 15 on the trench first side surfaces 46 and the trench second side surfaces 47 of the trenches 19 and the bottom portions 22 of the trenches 19. The semiconductor laser 100 of Embodiment 3 is manufactured by the above-described steps.

The semiconductor laser 100 and the semiconductor laser device 200 of Embodiment 3 have the same effects as the semiconductor laser 100 and the semiconductor laser device 200 of Embodiment 2. In the semiconductor laser 100 shown in FIG. 20, the insulating film 15 is not present on the bottom portions 22 of the trenches 19, and the anode electrode 12 having high thermal conductivity is disposed on the second buried layer 7. In the case where the anode 12 is made of gold, for example, the thermal conductivity is 300 W/(m·K). In the semiconductor laser 100 and the semiconductor laser device 200 of Embodiment 3, heat generated from the active layer 3 is more easily dissipated from the bottom portions 22 of the trenches 19 due to the arranged metal at the bottom portions 22 of the trenches 19 as well as from the positive side of the protruding portion 18 in the z-direction and the positive side of the end regions 24 in the z-direction than in the semiconductor laser 100 and the semiconductor laser device 200 of Embodiment 2, thereby improving the high temperature characteristics. Note that the metal of the bottom portions 22 of the trenches 19 may not be connected to the anode electrode 12, and the metal may not be disposed on the bottom portions 22 of the trenches 19. Even when the metal is not disposed on the bottom portions 22 of the trenches 19, the heat is dissipated to the heat sink 17 via the connection member 14 filled in the trenches 19.

As described above, the semiconductor laser 100 of Embodiment 3 includes the ridge 5 formed on the n-type semiconductor substrate 1 and the buried layer 25 buried so as to cover both sides of the ridge opposite to each other in the direction perpendicular to the extension direction of the ridge 5, and is a semiconductor laser mounted from the surface on the side where the ridge 5 protrudes. The z-direction, the y-direction, and the x-direction are as described above. The ridge 5 includes the n-type cladding layer 2, the active layer 3, and the p-type first cladding layer 4, which are sequentially formed from the side of the n-type semiconductor substrate 1. The buried layer 25 includes the p-type first buried layer 6 that is in contact with the side surface of the ridge 5 on the positive side in the x-direction and the side surface of the ridge 5 on the negative side in the x-direction, the second buried layer 7, and the n-type third buried layer 8. The semiconductor laser 100 includes the p-type second cladding layer 9, the p-type contact layer 10, which are sequentially formed on the positive side of the ridge 5 in the z-direction and on the positive side of the n-type third buried layer 8 in the z-direction in this order from the side of the n-type semiconductor substrate 1, the front surface-side electrode (anode electrode 12) connected to the p-type contact layer 10, and the semi-insulating layer 11, the semi-insulating layer 11 being formed on the outer edges separated in the x-direction from the ridge portion 50 including the ridge 5 and the p-type first buried layer 6 in contact with two side surfaces of the ridge 5. The semi-insulating layer 11 is formed on the positive side in the z-direction at the sides toward the x-direction ends (x-direction ends 29a and 29b) in the semiconductor laser 100. Between the side surface of the ridge portion 50 on the positive side in the x-direction and the end on the positive side in the x-direction in the semiconductor laser 100 (x-direction end 29b), and between the side surface of the ridge portion 50 on the negative side in the x-direction and the end on the negative side in the x-direction in the semiconductor laser 100 (x-direction end 29a), the trenches 19 are formed to extend in the y-direction. Each of the trenches 19 penetrates the p-type contact layer 10, the p-type second cladding layer 9, and the n-type third buried layer 8, and the bottom portions 22 of the trenches 19 are at the same position as the active layer surface position 44 that is a positive side position of the active layer 3 in the z-direction in the second buried layer 7 or the position of the bottom portions 22 of the trenches 19 is more distant from the n-type semiconductor substrate 1 than the active layer surface position 44 in the second buried layer 7. The front surface-side electrode (anode electrode 12) is connected to the p-type contact layer 10 in the protruding portion 18 formed between the two trenches 19. The semi-insulating layer 11 is formed on the positive side of the p-type contact layer 10 in the z-direction from the trench first side surfaces 46 of the trenches 19 to the x-direction ends (x-direction ends 29a, 29b) opposite to the protruding portion 18 of the semiconductor laser 100. The insulating film 15 is provided on the trench first side surfaces 46 and the trench second side surfaces 47 of the trenches 19, and the front surface-side electrode (the anode electrode 12) covers the insulating film 15 on the trench first side surfaces 46 and the trench second side surfaces 47 and the bottom portions 22 of the trenches 19. With this configuration, the semiconductor laser 100 of Embodiment 3 includes the semi-insulating layer 11 that is separated in the x-direction from the ridge portion 50 having the active layer 3 and is at the outer edges on the side opposite to the n-type semiconductor substrate 1. Therefore, when the semiconductor laser 100 is mounted from the side of the front surface-side electrode (anode electrode 12), excellent heat dissipation can be achieved while the leakage current that does not contribute to the laser oscillation is suppressed.

The semiconductor laser production method of Embodiment 3 is a semiconductor laser production method of manufacturing the semiconductor laser 100 including the ridge 5 formed on the n-type semiconductor substrate 1 and the buried layer 25 buried so as to cover both sides of the ridge opposite to each other in the direction perpendicular to the extension direction of the ridge 5. The semiconductor laser production method of Embodiment 3 includes the ridge forming step, the burying step, the stacking step, the trench forming step, the contact layer exposing step, the insulating film forming step, and the front surface-side electrode forming step, which are described below. In the ridge forming step, the n-type cladding layer 2, the active layer 3, and the p-type first cladding layer 4 are sequentially formed on the n-type semiconductor substrate 1, and then by the etching down to a position lower than the negative side of the active layer 3 in the z-direction, which is on the side of the n-type semiconductor substrate 1, the ridge 5 that includes the n-type cladding layer 2, the active layer 3, and the p-type first cladding layer 4 and in which the side surface on the positive side in the x-direction and the side surface on the negative side in the x-direction are exposed is formed. In the burying step, the p-type first buried layer 6 is formed on the side surface on the positive side in the x-direction and the side surface on the negative side in the x-direction in the ridge 5, and the ridge 5 is buried by the second buried layer 7 and the n-type third buried layer 8 that are sequentially formed to the position higher than the active layer surface position 44 that is a positive side position of the active layer 3 in the z-direction. In the stacking step, the p-type second cladding layer 9, the p-type contact layer 10, and the semi-insulating layer 11 are sequentially formed on the positive side of the ridge 5 in the z-direction and on the positive side of the n-type third buried layer 8 in the z-direction. In the trench forming step, the trenches 19 are formed to penetrate the semi-insulating layer 11, the p-type contact layer 10, the p-type second cladding layer 9, and the n-type third buried layer 8 at the two outer edges separated on the positive side and the negative side in the x-direction from the ridge portion 50 including the ridge 5 and the p-type first buried layer 6 that is in contact with the two side surfaces of the ridge 5, and the trenches 19 are formed such that the bottom portions 22 in the z-direction is the same as the active layer surface position 44 of the active layer 3 in the second buried layer 7 or the bottom portions 22 are positioned on the positive side from the active layer surface position 44. In the contact layer exposing step, the semi-insulating layer 11 formed on the protruding portion 18 between the two trenches 19 is etched to expose the p-type contact layer 10. In the insulating film forming step, the insulating film 15 is formed on both side surfaces (the trench first side surface 46 and the trench second side surface 47) in the x-direction of each of the trenches 19. In the front surface-side electrode forming step, the front surface-side electrode (the anode electrode 12) is formed so as to cover the p-type contact layer 10 on which the insulating film 15 of the protruding portion 18 is not formed in the insulating film forming step and to cover the insulating film 15 of both side surfaces (the trench first side surfaces 46 and the trench second side surfaces 47) of the trenches 19, and the bottom portions 22 of the trenches 19. With this configuration, the semiconductor laser production method of Embodiment 3 can manufacture the semiconductor laser 100 including the semi-insulating layer 11 that is separated in the x-direction from the ridge portion 50 having the active layer 3 and is at the outer edges on the side opposite to the n-type semiconductor substrate 1, so that excellent heat dissipation can be achieved while the leakage current not contributing to laser oscillation is suppressed when the semiconductor laser 100 is mounted from the side of the front surface-side electrode (anode electrode 12).

### Embodiment 4

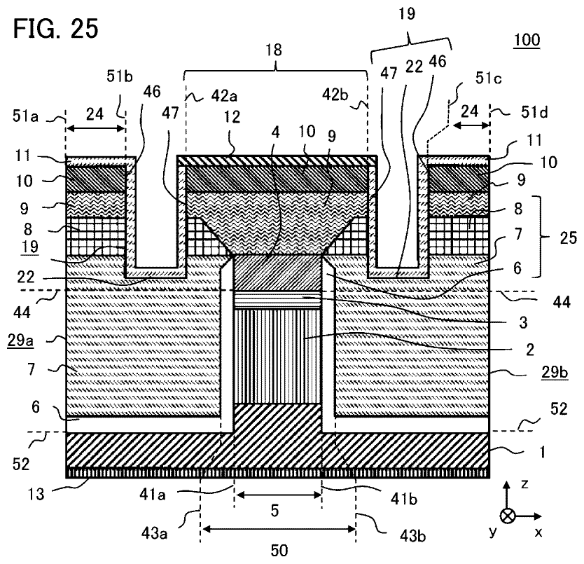

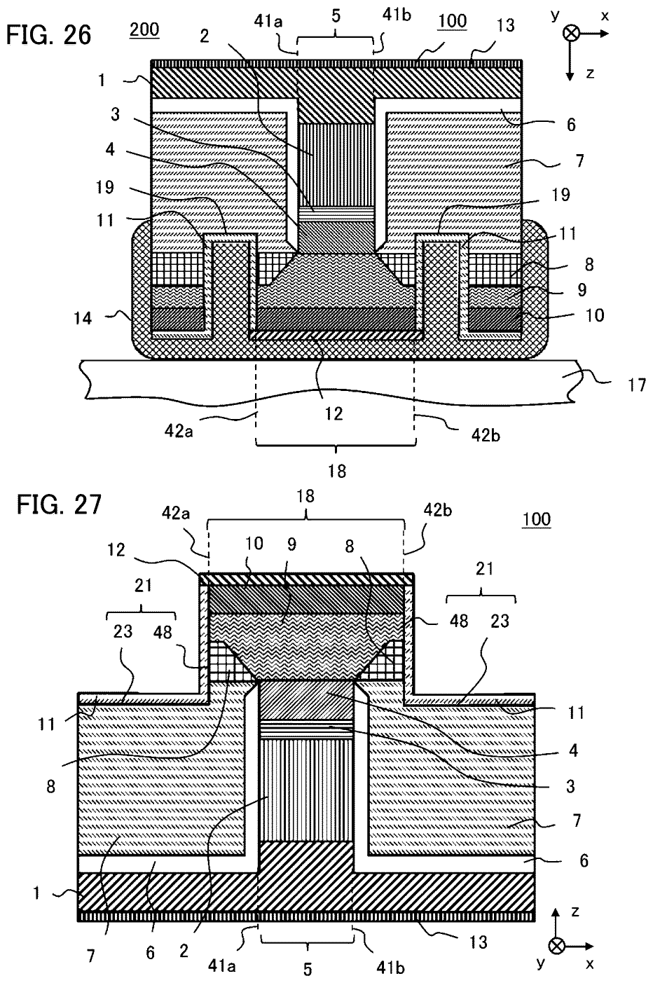

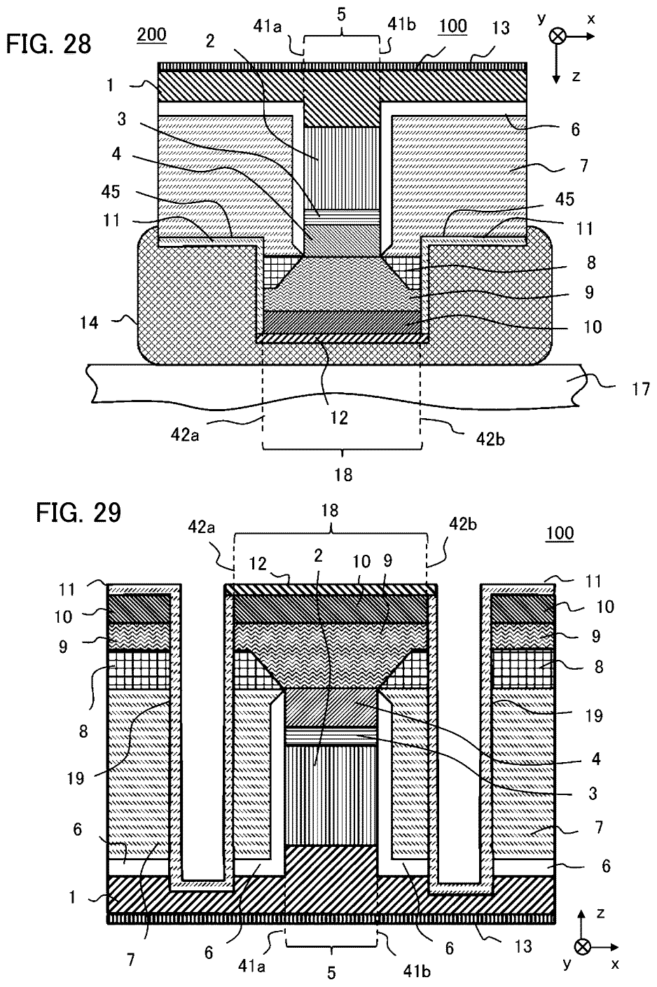

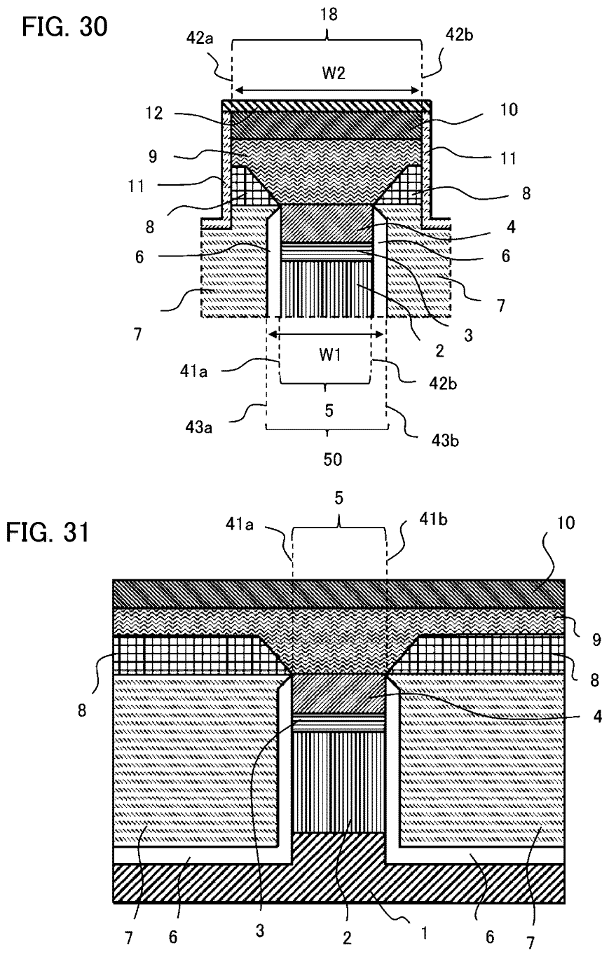

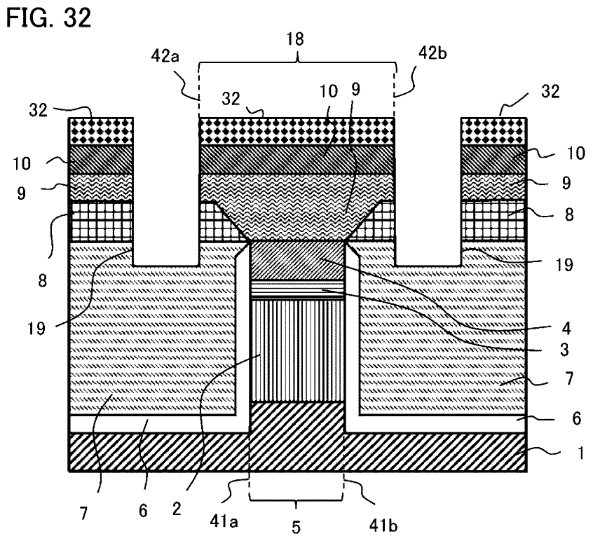

FIG. 25 is a diagram showing a cross-sectional structure of a first semiconductor laser according to Embodiment 4, and FIG. 26 is a diagram showing a cross-sectional structure of a first semiconductor laser device according to Embodiment 4. FIG. 27 is a diagram showing a cross-sectional structure of a second semiconductor laser according to Embodiment 4, and FIG. 28 is a diagram showing a cross-sectional structure of a second semiconductor laser device according to Embodiment 4. FIG. 29 is a diagram showing a cross-sectional structure of a third semiconductor laser according to Embodiment 4. FIG. 30 is a diagram showing a width of the protruding portion in the semiconductor laser of Embodiment 4. FIG. 31 to FIG. 34 are diagrams showing a method of manufacturing the semiconductor laser of FIG. 25. The first and third semiconductor lasers 100 of Embodiment 4 are different from the semiconductor laser 100 of Embodiment 2 in that the inner surfaces of the trenches 19 are covered not with the insulating film 15 but with the semi-insulating layer 11. Further, the second semiconductor laser 100 of Embodiment 4 is different from the semiconductor laser 100 of Embodiment 2 in that the trenches 19 are changed to receded portions 21 having bottom portions 23 extending to the x-direction ends 29a and 29b, and the bottom portions 23 and receded portion side surfaces 48 in the receded portions 21 are covered with the semi-insulating layer 11. Since the bottom portions 23 of the receded portions 21 extend to the x-direction ends 29a and 29b in the x-direction, the bottom portions 23 of the receded portions 21 can also be referred to as the end regions 24. Differences from the semiconductor laser 100 and the semiconductor laser device 200 of Embodiment 2 will be mainly described.

The first semiconductor laser 100 of Embodiment 4 shown in FIG. 25 and the third semiconductor laser 100 of Embodiment 4 shown in FIG. 29 are examples in which the trenches 19 are provided, and the inner surfaces of the trenches 19 and the surface of the p-type contact layer 10 in the end regions 24 are covered with the semi-insulating layer 11. The bottom portions 22 of the trenches 19 should be disposed at any position in the z-direction between the p-type second cladding layer 9 and the inside of the n-type semiconductor substrate 1. The third semiconductor laser 100 of Embodiment 4 shown in FIG. 29 is an example in which the bottom portions 22 of the trenches 19 are disposed at a position of the n-type semiconductor substrate 1 in the z-direction. FIG. 29 shows an example in which the bottom portions 22 of the trenches 19 are disposed closer to the rear surface side of the n-type semiconductor substrate 1 than the surface in the n-type semiconductor substrate 1 formed in the ridge 5. In the first semiconductor laser 100 of Embodiment 4 shown in FIG. 25 and the third semiconductor laser 100 of Embodiment 4 shown in FIG. 29, the semi-insulating layer 11 is formed directly on the inner surfaces of the trenches 19, and on the positive side of the p-type contact layer 10 in the z-direction from the trench first side surfaces 46 of the trenches 19 to the x-direction ends (x-direction ends 29a and 29b) opposite to the protruding portion 18 of the semiconductor laser 100.

The second semiconductor laser 100 of Embodiment 4 includes the receded portions 21 formed to extend in the y-direction between the side surface of the ridge portion 50 on the positive side in the x-direction and the end on the positive side in the x-direction in the semiconductor laser 100 (x-direction end 29b) and between the side surface of the ridge portion 50 on the negative side in the x-direction and the end on the negative side in the x-direction in the semiconductor laser 100 (x-direction end 29a). In each of the receded portions 21, the p-type contact layer 10 is removed, and the bottom portions 23 of the receded portions 21 are disposed at any position in the z-direction between the p-type second cladding layer 9 and the inside of the n-type semiconductor substrate 1. The semi-insulating layer 11 is formed directly on the side surface (the receded portion side surface 48) and the bottom portion 23 of the receded portion 21 on the positive side in the x-direction and on the side surface (the receded portion side surface 48) and the bottom portion 23 of the receded portion 21 on the negative side in the x-direction.

FIG. 26 shows an example of the semiconductor laser device 200 in which the first semiconductor laser 100 of Embodiment 4 is mounted on the heat sink 17 by the junction-down mounting while the connection member 14 is filled in the trenches 19 and the connection member 14 in a position on the negative side in the z-direction covers a part of the second buried layer 7 at the x-direction ends 29a and 29b. FIG. 28 shows an example of the semiconductor laser device 200 in which the second semiconductor laser 100 of Embodiment 4 is mounted on the heat sink 17 by the junction-down mounting while the connection member 14 is filled in the receded portions 21 and the connection member 14 in a position on the negative side in the z-direction covers a part of the second buried layer 7 at the x-direction ends 29a and 29b. The protruding portion 18 formed between the two receded portions 21 is the same as the protruding portion 18 formed between the two trenches 19. The protruding portion width W2, which is the width of the protruding portions 18 in the x-direction, is larger than the ridge width W1, which is the width of the ridge portion 50 in the x-direction.

FIG. 25 and FIG. 29 show an example in which the semi-insulating layer 11 on the inner surface of the trenches 19 and on the positive side of the end regions 24 in the z-direction are exposed. However, this is not a limitation, and the surface of the semi-insulating layer 11 may be covered with the anode electrode 12 or a metal that is not connected to the anode electrode 12. FIG. 27 shows an example in which the semi-insulating layer 11 on the receded portion side surfaces 48 and the positive side of the bottom portions 23 in the z-direction in the receded portions 21 are exposed. However, this is not a limitation, and the surface of the semi-insulating layer 11 may be covered with the anode electrode 12 or a metal that is not connected to the anode electrode 12.

Next, a method of manufacturing the first or third semiconductor laser 100 of Embodiment 4 will be described with reference to the above-described FIG. 4 to FIG. 7 and an example shown in FIG. 31 to FIG. 34. The ridge forming step and the burying step shown in FIG. 4 to FIG. 7 are the same as those of Embodiment 1. Note that FIG. 7 shows the state before the start of the stacking step and also shows the state at the end of the burying step. After the burying step shown in FIG. 7, the stacking step shown in FIG. 31 is performed in which the p-type second cladding layer 9 and the p-type contact layer 10 are sequentially formed on the positive side of the ridge 5 in the z-direction and on the positive side of the n-type third buried layer 8 in the z-direction. Then, the trench forming step shown in FIG. 32 is performed. In the trench forming step, two trenches 19 are formed on both sides of the ridge portion 50 in the x-direction using a resist mask 32 in the semiconductor layer formed up to the p-type contact layer 10 such that the bottom portions 22 are located at any position in the z-direction between the p-type second cladding layer 9 and the inside of the n-type semiconductor substrate 1. More specifically, in the trench forming step, the p-type contact layer 10 is etched at two outer edges separated from the ridge portion 50 on the positive side and the negative side in the x-direction, and the trenches 19 are formed by the etching such that the position of the bottom portions 22 in the z-direction is to be any position in the z-direction between the p-type second cladding layer 9 and the inside of the n-type semiconductor substrate 1.

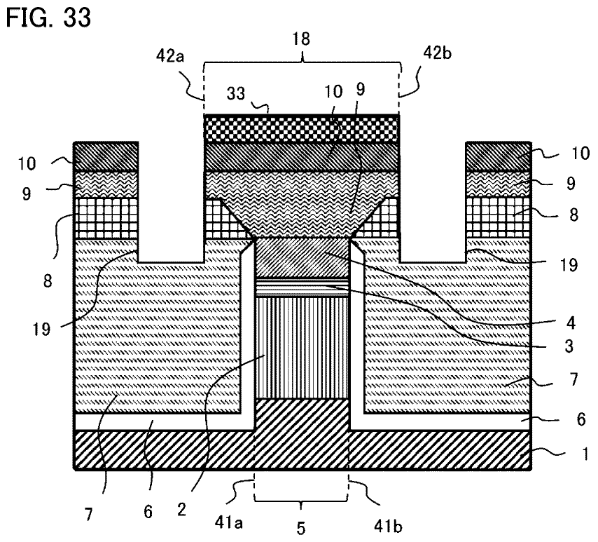

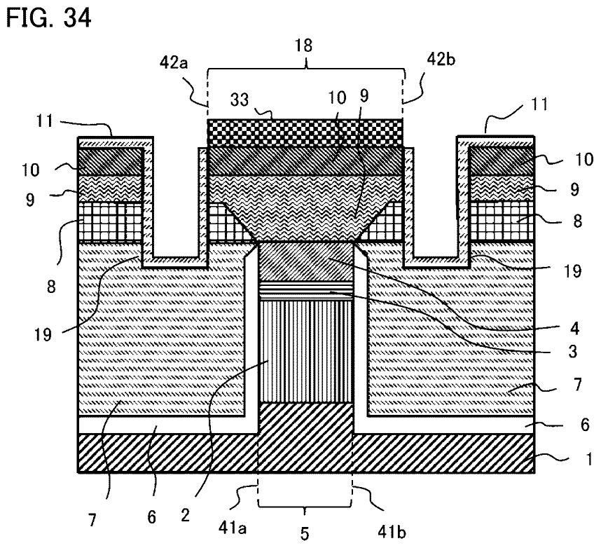

Next, a semi-insulating layer forming step of forming the semi-insulating layer 11 is performed. In the semi-insulating layer forming step, as shown in FIG. 33, a second mask 33 made of SiO₂, SiN, or the like is formed on the positive side of the protruding portion 18 in the z-direction. As shown in FIG. 34, the semi-insulating layer 11 is formed in a region other than the positive side of the protruding portion 18 in the z-direction by using the second mask 33. The semi-insulating layer 11 is formed by selective growth. More specifically, the semi-insulating layer 11 is formed directly on the positive side of the p-type contact layer 10 in the z-direction on the sides that are separated in the x-direction from the protruding portion 18 formed between the two trenches 19 and are outside the trenches 19, and on the inner surfaces of the two trenches 19. Thereafter, the second mask 33 is removed by using buffered hydrofluoric acid or hydrofluoric acid.

Thereafter, the front surface-side electrode forming step of forming the anode electrode 12 so as to cover the p-type contact layer 10 on which the semi-insulating layer 11 of the protruding portion 18 is not formed in the insulating layer forming step, and the rear surface-side electrode forming step of forming the cathode electrode 13 on the rear surface side of the n-type semiconductor substrate 1, that is, on the negative side in the z-direction, are performed. The anode electrode 12 is patterned using a resist mask. Through the above steps, the first or third semiconductor laser 100 of Embodiment 4 is manufactured.

Next, a method of manufacturing the second semiconductor laser 100 of Embodiment 4 will be described with reference to an example. The steps up to FIG. 31 are the same as those in the method of manufacturing the first or third semiconductor laser 100 of Embodiment 4. Thereafter, similarly to the trench forming step, a receded portion forming step is performed. In the receded portion forming step, in the semiconductor layers formed up to the p-type contact layer 10, two receded portions 21 are formed on both sides of the ridge portion 50 in the x-direction using the resist mask 32 formed on the positive side of the protruding portion 18 in the z-direction such that the bottom portions 23 is located at any position in the z-direction between the p-type second cladding layer 9 and the inside of the n-type semiconductor substrate 1. More specifically, in the receded portion forming step, the p-type contact layer 10 is etched at two outer edges separated from the ridge portion 50 on the positive side and the negative side in the x-direction, and the receded portions 21 are formed by the etching down to the position of the bottom portions 23 in the z-direction to be any position in the z-direction between the p-type second cladding layer 9 and the inside of the n-type semiconductor substrate 1.

Next, the semi-insulating layer forming step of forming the semi-insulating layer 11 is performed. In the semi-insulating layer forming step, the second mask 33 is formed on the positive side of the protruding portion 18 in the z-direction as in FIG. 33. Using the second mask 33, the semi-insulating layer 11 is formed in a region other than the positive side of the protruding portion 18 in the z-direction as in FIG. 34. More specifically, the semi-insulating layer 11 is formed directly on the side surface (the receded portion side surface 48) and the bottom portion 23 of the receded portion 21 on the positive side in the x-direction, and on the side surface (the receded portion side surface 48) and the bottom portion 23 of the receded portion 21 on the negative side in the x-direction. Thereafter, the second mask 33 is removed by using buffered hydrofluoric acid or hydrofluoric acid.

Next, the front surface-side electrode forming step of forming the anode electrode 12 so as to cover the p-type contact layer 10 on which the semi-insulating layer 11 of the protruding portion 18 is not formed in the insulating layer forming step, and the rear surface-side electrode forming step of forming the cathode electrode 13 on the rear surface side of the n-type semiconductor substrate 1, that is, on the negative side in the z-direction, are performed. The anode electrode 12 is patterned by using a resist mask. The second semiconductor laser 100 of Embodiment 4 is manufactured by the above-described steps.

In the semiconductor laser 100 of Embodiment 4, the area of the n-type third buried layer 8 on the side of the second buried layer 7 can be reduced by the trenches 19 or the receded portions 21, and the area of the n-type third buried layer 8 on the side of the second buried layer 7 can be reduced also in the vicinity of the active layer 3. Therefore, the semiconductor laser 100 and the semiconductor laser device 200 of Embodiment 4 have the same effects as the semiconductor laser 100 and the semiconductor laser device 200 of Embodiment 2. In the semiconductor laser 100 of Embodiment 4, since the semi-insulating layer 11 having high thermal conductivity is used instead of the insulating film 15, the heat can be dissipated also from the inner surfaces (the trench first side surfaces 46, the trench second side surfaces 47, and the bottom portions 22) of the trenches 19 or the receded portion side surfaces and the bottom portions 23 of the receded portions 21, so that high-temperature characteristics can be improved as compared with the semiconductor laser 100 of Embodiment 2.

As described above, the first or third semiconductor laser 100 of Embodiment 4 includes the ridge 5 formed on the n-type semiconductor substrate 1 and the buried layer 25 buried so as to cover both sides of the ridge opposite to each other in the direction perpendicular to the extension direction of the ridge 5, and is a semiconductor laser mounted from the surface on the side where the ridge 5 protrudes. The z-direction, the y-direction, and the x-direction are as described above. The ridge 5 includes the n-type cladding layer 2, the active layer 3, and the p-type first cladding layer 4, which are sequentially formed from the side of the n-type semiconductor substrate 1. The buried layer 25 includes the p-type first buried layer 6 that is in contact with the side surface of the ridge 5 on the positive side in the x-direction and the side surface of the ridge 5 on the negative side in the x-direction, the second buried layer 7, and the n-type third buried layer 8. The semiconductor laser 100 includes the p-type second cladding layer 9, the p-type contact layer 10, which are sequentially formed on the positive side of the ridge 5 in the z-direction and on the positive side of the n-type third buried layer 8 in the z-direction in this order from the side of the n-type semiconductor substrate 1, the front surface-side electrode (anode electrode 12) connected to the p-type contact layer 10, and the semi-insulating layer 11, the semi-insulating layer 11 being formed on the outer edges separated in the x-direction from the ridge portion 50 including the ridge 5 and the p-type first buried layer 6 in contact with two side surfaces of the ridge 5. The semi-insulating layer 11 is formed on the positive side in the z-direction on the sides of the x-direction ends (x-direction ends 29a and 29b) in the semiconductor laser 100. Between the side surface of the ridge portion 50 on the positive side in the x-direction and the end on the positive side in the x-direction in the semiconductor laser 100 (x-direction end 29b), and between the side surface of the ridge portion 50 on the negative side in the x-direction and the end on the negative side in the x-direction in the semiconductor laser 100 (x-direction end 29a), the trenches 19 are formed to extend in the y-direction. Each of the trenches 19 penetrates the p-type contact layer 10, and the bottom portions 22 of the trenches 19 are disposed at any position in the z-direction between the p-type second cladding layer 9 and the inside of the n-type semiconductor substrate 1. The front surface-side electrode (anode electrode 12) is connected to the p-type contact layer 10 in the protruding portion 18 formed between the two trenches 19. The semi-insulating layer 11 is formed directly on the inner surfaces of the trenches 19 and on the positive side of the p-type contact layer 10 in the z-direction from the trench first side surfaces 46 of the trenches 19 to the x-direction ends (x-direction end 29a, 29b) opposite to the protruding portion 18 of the semiconductor laser 100. With this configuration, the first or the third semiconductor laser 100 of Embodiment 4 includes the semi-insulating layer 11 that is separated in the x-direction from the ridge portion 50 having the active layer 3 and is at the outer edges on the side opposite to the n-type semiconductor substrate 1. Therefore, when the semiconductor laser 100 is mounted from the side of the front surface-side electrode (anode electrode 12), excellent heat dissipation can be achieved while the leakage current that does not contribute to the laser oscillation is suppressed.

The third semiconductor laser 100 of Embodiment 4 includes the ridge 5 formed on the n-type semiconductor substrate 1 and the buried layer 25 buried so as to cover both sides of the ridge opposite to each other in the direction perpendicular to the extension direction of the ridge 5, and is a semiconductor laser mounted from the surface from which the ridge 5 protrudes. The ridge 5 includes the n-type cladding layer 2, the active layer 3, and the p-type first cladding layer 4, which are sequentially formed from the side of the n-type semiconductor substrate 1. The buried layer 25 includes the p-type first buried layer 6 that is in contact with the side surface of the ridge 5 on the positive side in the x-direction and the side surface of the ridge 5 on the negative side in the x-direction, the second buried layer 7, and the n-type third buried layer 8. The semiconductor laser 100 includes the p-type second cladding layer 9, the p-type contact layer 10, which are sequentially formed on the positive side of the ridge 5 in the z-direction and on the positive side of the n-type third buried layer 8 in the z-direction in this order from the side of the n-type semiconductor substrate 1, the front surface-side electrode (anode electrode 12) connected to the p-type contact layer 10, and the semi-insulating layer 11, the semi-insulating layer 11 being formed on the outer edges separated in the x-direction from the ridge portion 50 including the ridge 5 and the p-type first buried layer 6 in contact with two side surfaces of the ridge 5. The semi-insulating layer 11 is formed on the positive side in the z-direction on the sides of the x-direction ends (x-direction ends 29a and 29b) in the semiconductor laser 100. The receded portions 21 formed to extend in the y-direction are provided between the side surface of the ridge portion 50 on the positive side in the x-direction and the end on the positive side in the x-direction in the semiconductor laser 100 (x-direction end 29b) and between the side surface of the ridge portion 50 on the negative side in the x-direction and the end on the negative side in the x-direction in the semiconductor laser 100 (x-direction end 29a). In each of the receded portions 21, the p-type contact layer 10 is removed, and the bottom portions 23 of the receded portions 21 are disposed at any position in the z-direction between the p-type second cladding layer 9 and the inside of the n-type semiconductor substrate 1. The front surface-side electrode (anode electrode 12) is connected to the p-type contact layer 10 in the protruding portion 18 formed between the two receded portions 21. The semi-insulating layer 11 is formed directly on the side surface (receded portion side surface 48) and the bottom portion 23 in the receded portion 21 on the positive side in the x-direction, and on the side surface (receded portion side surface 48) and the bottom portion 23 in the receded portion on the negative side in the x-direction. With this configuration, the third semiconductor laser 100 of Embodiment 4 includes the semi-insulating layer 11 that is separated in the x-direction from the ridge portion 50 having the active layer 3 and is at the outer edges on the side opposite to the n-type semiconductor substrate 1. Therefore, when the semiconductor laser 100 is mounted from the side of the front surface-side electrode (anode electrode 12), excellent heat dissipation can be achieved while the leakage current that does not contribute to the laser oscillation is suppressed.

The semiconductor laser production method of Embodiment 4 is a semiconductor laser production method of manufacturing the semiconductor laser 100 including the ridge 5 formed on the n-type semiconductor substrate 1 and the buried layer 25 buried so as to cover both sides of the ridge opposite to each other in the direction perpendicular to the extension direction of the ridge 5. The semiconductor laser production method of Embodiment 4 includes the ridge forming step, the burying step, the stacking step, the trench forming step, the semi-insulating layer forming step, and the front surface-side electrode forming step, which will be described below. In the ridge forming step, the n-type cladding layer 2, the active layer 3, and the p-type first cladding layer 4 are sequentially formed on the n-type semiconductor substrate 1, and then by the etching down to a position lower than the negative side of the active layer 3 in the z-direction, which is on the side of the n-type semiconductor substrate 1, the ridge 5 that includes the n-type cladding layer 2, the active layer 3, and the p-type first cladding layer 4 and in which the side surface on the positive side in the x-direction and the side surface on the negative side in the x-direction are exposed is formed. In the burying step, the p-type first buried layer 6 is formed on the side surface on the positive side in the x-direction and the side surface on the negative side in the x-direction in the ridge 5, and the ridge 5 is buried by the second buried layer 7 and the n-type third buried layer 8 that are sequentially formed to the position higher than the active layer surface position 44 that is a positive side position of the active layer 3 in the z-direction. In the stacking step, the p-type second cladding layer 9 and the p-type contact layer 10 are sequentially formed on the positive side of the ridge 5 in the z-direction and on the positive side of the n-type third buried layer 8 in the z-direction. In the trench forming step, the p-type contact layer 10 is etched at two outer edges separated on the positive side and the negative side in the x-direction from the ridge portion 50 including the ridge 5 and the p-type first buried layer 6 in contact with two side surfaces of the ridge 5, and the trenches 19 are formed by the etching such that the position of the bottom portions 22 in the z-direction is to be any position in the z-direction between the p-type second cladding layer 9 and the inside of the n-type semiconductor substrate 1. In the semi-insulating layer forming step, the semi-insulating layer 11 is formed directly on the positive side of the p-type contact layer 10 in the z-direction on the sides that are separated in the x-direction from the protruding portion 18 formed between the two trenches 19 and are outside the trenches 19, and on the inner surfaces of the two trenches 19. In the front surface-side electrode forming step, the front surface-side electrode (anode electrode 12) is formed so as to cover the p-type contact layer 10 on which the semi-insulating layer 11 of the protruding portion 18 is not formed in the semi-insulating layer forming step. With this configuration, the semiconductor laser production method of Embodiment 4 can manufacture the semiconductor laser 100 including the semi-insulating layer 11 that is separated in the x-direction from the ridge portion 50 having the active layer 3 and is at the outer edges on the side opposite to the n-type semiconductor substrate 1, so that excellent heat dissipation can be achieved while the leakage current not contributing to laser oscillation is suppressed when the semiconductor laser 100 is mounted from the side of the front surface-side electrode (anode electrode 12).

The other semiconductor laser production method of Embodiment 4 is a semiconductor laser production method of manufacturing the semiconductor laser 100 including the ridge 5 formed on the n-type semiconductor substrate 1 and the buried layer 25 buried so as to cover both sides of the ridge opposite to each other in the direction perpendicular to the extension direction of the ridge 5. The other semiconductor laser production method of Embodiment 4 includes the ridge forming step, the burying step, the stacking step, the receded portion forming step, the semi-insulating layer forming step, and the front surface-side electrode forming step, which will be described below. In the ridge forming step, the n-type cladding layer 2, the active layer 3, and the p-type first cladding layer 4 are sequentially formed on the n-type semiconductor substrate 1, and then by the etching down to a position lower than the negative side of the active layer 3 in the z-direction, which is on the side of the n-type semiconductor substrate 1, the ridge 5 that includes the n-type cladding layer 2, the active layer 3, and the p-type first cladding layer 4 and in which the side surface on the positive side in the x-direction and the side surface on the negative side in the x-direction are exposed is formed. In the burying step, the p-type first buried layer 6 is formed on the side surface on the positive side in the x-direction and the side surface on the negative side in the x-direction in the ridge 5, and the ridge 5 is buried by the second buried layer 7 and the n-type third buried layer 8 that are sequentially formed to the position higher than the active layer surface position 44 that is a positive side position of the active layer 3 in the z-direction. In the stacking step, the p-type second cladding layer 9 and the p-type contact layer 10 are sequentially formed on the positive side of the ridge 5 in the z-direction and on the positive side of the n-type third buried layer 8 in the z-direction. In the receded portions forming step, the p-type contact layer 10 is etched at two outer edges separated on the positive side and the negative side in the x-direction from the ridge portion 50 including the ridge 5 and the p-type first buried layer 6 in contact with two side surfaces of the ridge 5, and the receded portions 21 are formed by the etching down to the position of the bottom portions 23 in the z-direction to be any position in the z-direction between the p-type second cladding layer 9 and the inside of the n-type semiconductor substrate 1. In the semi-insulating layer forming step, the semi-insulating layer 11 is formed directly on the side surface (the receded portion side surface 48) and the bottom portion 23 of the receded portion 21 on the positive side in the x-direction, and on the side surface (the receded portion side surface 48) and the bottom portion 23 of the receded portion 21 on the negative side in the x-direction. In the front surface-side electrode forming step, the front surface-side electrode (anode electrode 12) is formed so as to cover the p-type contact layer 10 on which the semi-insulating layer 11 of the protruding portion 18 is not formed in the semi-insulating layer forming step in the protruding portion 18 formed between the two receded portions 21. With this configuration, the other semiconductor laser production method of Embodiment 4 can manufacture the semiconductor laser 100 including the semi-insulating layer 11 that is separated in the x-direction from the ridge portion 50 having the active layer 3 and is at the outer edges on the side opposite to the n-type semiconductor substrate 1, so that excellent heat dissipation can be achieved while the leakage current not contributing to laser oscillation is suppressed when the semiconductor laser 100 is mounted from the side of the front surface-side electrode (anode electrode 12).

### Embodiment 5

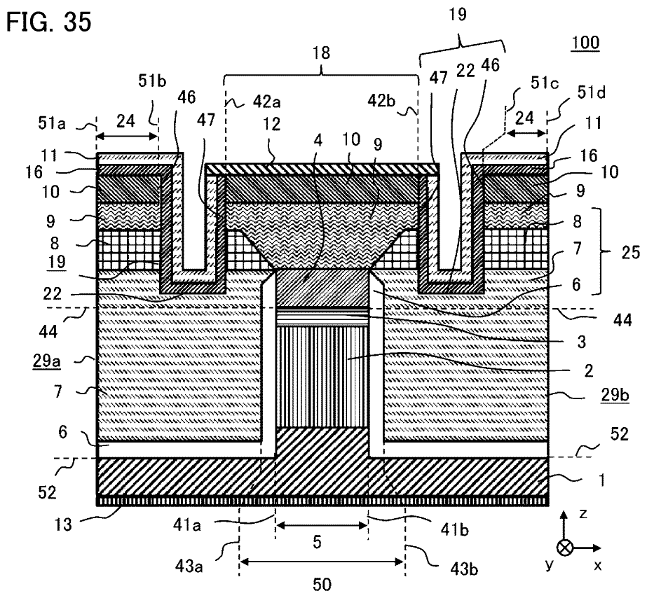

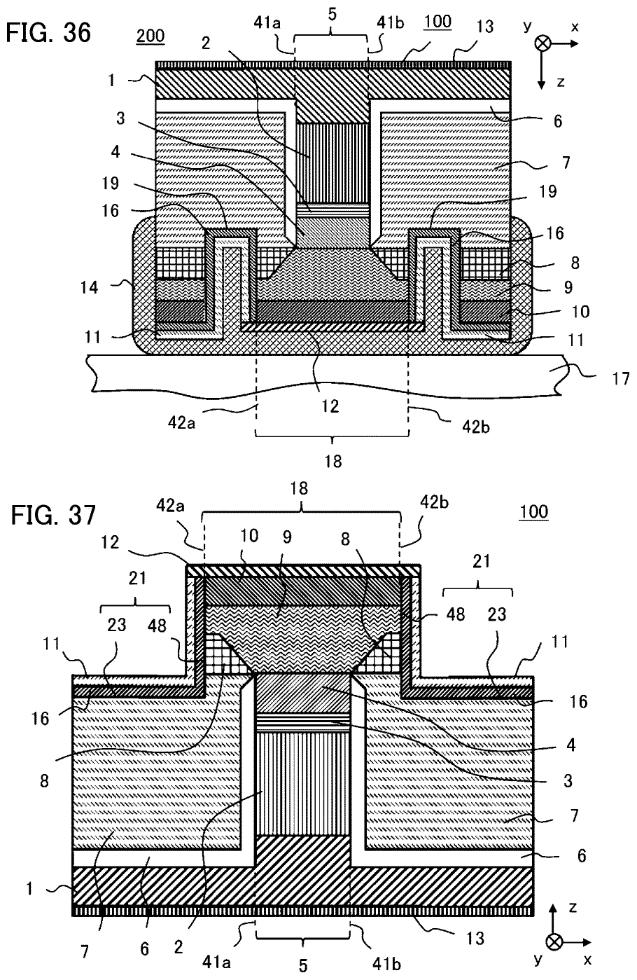

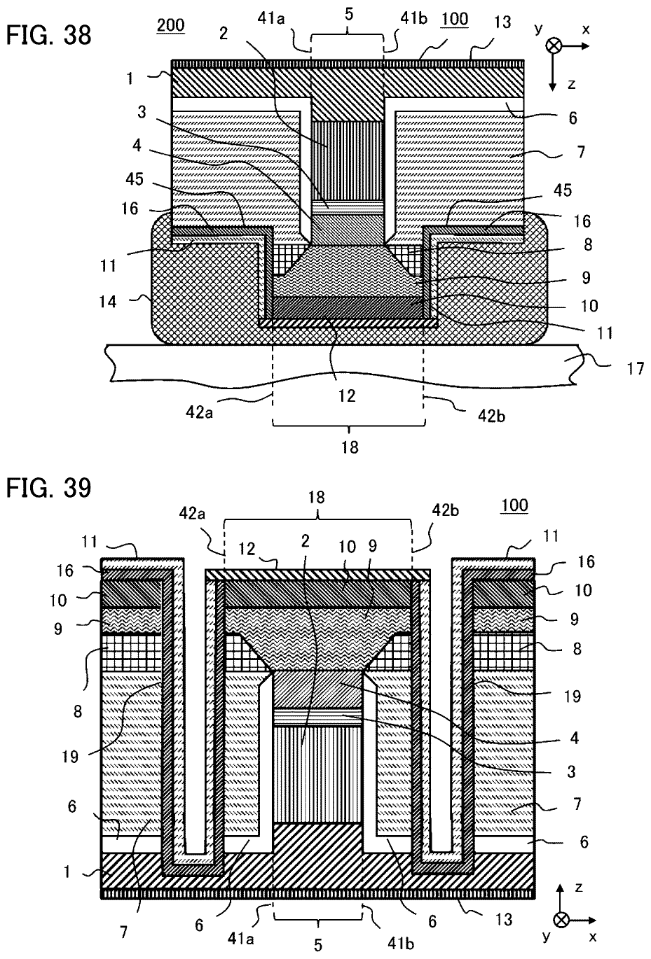

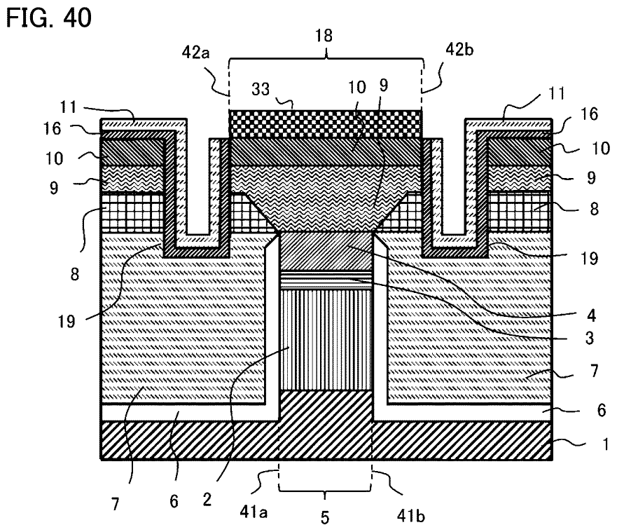

FIG. 35 is a diagram showing a cross-sectional structure of a first semiconductor laser according to Embodiment 5, and FIG. 36 is a diagram showing a cross-sectional structure of a first semiconductor laser device according to Embodiment 5. FIG. 37 is a diagram showing a cross-sectional structure of a second semiconductor laser device according to Embodiment 5, and FIG. 38 is a diagram showing a cross-sectional structure of a second semiconductor laser device according to Embodiment 5. FIG. 39 is a diagram showing a cross-sectional structure of a third semiconductor laser according to Embodiment 5. FIG. 40 is a diagram showing a method of manufacturing the semiconductor laser of FIG. 35. The semiconductor laser 100 of Embodiment 5 is different from the semiconductor laser 100 of Embodiment 4 in that the semi-insulating layer 11 is formed on both side surfaces of the protruding portion 18 in the x-direction and from both the side surfaces to the x-direction ends 29a and 29b, via an n-type diffusion block layer 16. Differences from the semiconductor laser 100 and the semiconductor laser device 200 of Embodiment 4 will be mainly described.

The first semiconductor laser 100 of Embodiment 5 shown in FIG. 35 and the third semiconductor laser 100 of Embodiment 5 shown in FIG. 39 are examples in which the trenches 19 are provided, and the inner surfaces of the trenches 19 and the surfaces of the p-type contact layer 10 in the end regions 24 are covered with the semi-insulating layer 11 via the n-type diffusion block layer 16. The bottom portions 22 of the trenches 19 should be disposed at any position in the z-direction between the p-type second cladding layer 9 and the inside of the n-type semiconductor substrate 1. The third semiconductor laser 100 of Embodiment 5 shown in FIG. 39 is an example in which the bottom portions 22 of the trenches 19 are disposed at a position of the n-type semiconductor substrate 1 in the z-direction. FIG. 39 shows an example in which the bottom portions 22 of the trenches 19 are disposed closer to the rear surface side of the n-type semiconductor substrate 1 than the surface in the n-type semiconductor substrate 1 formed in the ridge 5. In the first semiconductor laser 100 of Embodiment 5 shown in FIG. 35 and the third semiconductor laser 100 of Embodiment 5 shown in FIG. 39, the semi-insulating layer 11 is formed via the n-type diffusion block layer 16 on the positive side of the p-type contact layer 10 in the z-direction on the inner surfaces of the trenches 19 and from the trench first side surfaces 46 of the trenches 19 to the x-direction ends (x-direction ends 29a and 29b) opposite to the protruding portion 18 of the semiconductor laser 100.

The second semiconductor laser 100 of Embodiment 5 shown in FIG. 37 includes two receded portions 21, and in each of the receded portions 21, the p-type contact layer 10 is removed, and the bottom portions 23 of the receded portions 21 are disposed at any position in the z-direction between the p-type second cladding layer 9 and the inside of the n-type semiconductor substrate 1. The semi-insulating layer 11 is formed on the side surface (the receded portion side surface 48) and the bottom portion 23 of the receded portion 21 on the positive side in the x-direction and on the side surface (the receded portion side surface 48) and the bottom portion 23 of the receded portion 21 on the negative side in the x-direction via the n-type diffusion block layer 16.

Next, a method of manufacturing the first or third semiconductor laser 100 of Embodiment 5 will be described using the above-described FIG. 4 to FIG. 7 and FIG. 31 to FIG. 33, and an example shown in FIG. 40. The method of manufacturing the first or third semiconductor laser 100 of Embodiment 5 is different from the method of manufacturing the first or third semiconductor laser 100 of Embodiment 4 in the semi-insulating layer forming step. The ridge forming step and the burying step shown in FIG. 4 to FIG. 7 are the same as those of Embodiment 1. Note that FIG. 7 shows the state before the start of the stacking step and also shows the state at the end of the burying step. The stacking step, the trench forming step, and the second mask forming step of the semi-insulating layer forming step shown in FIG. 31 to FIG. 33 are the same as those of Embodiment 4.

The semi-insulating layer forming step will be described. As shown in FIG. 40, the n-type diffusion block layer 16 and the semi-insulating layer 11 are sequentially formed in a region other than the positive side of the protruding portion 18 in the z-direction using the second mask 33. The n-type diffusion block layer 16 and the semi-insulating layer 11 are formed by selective growth. More specifically, the semi-insulating layer 11 is formed on the positive side of the p-type contact layer 10 in the z-direction on the sides that are separated in the x-direction from the protruding portion 18 formed between the two trenches 19 and are outside the trenches 19, and on the inner surfaces of the two trenches 19 via the n-type diffusion block layer 16. Thereafter, the second mask 33 is removed by using buffered hydrofluoric acid or hydrofluoric acid.

Next, the front surface-side electrode forming step of forming the anode electrode 12 so as to cover the p-type contact layer 10 on which the semi-insulating layer 11 of the protruding portion 18 is not formed in the insulating layer forming step, and the rear surface-side electrode forming step of forming the cathode electrode 13 on the rear surface side of the n-type semiconductor substrate 1, that is, on the negative side in the z-direction, are performed. The anode electrode 12 is patterned using a resist mask. The first or third semiconductor laser 100 of Embodiment 5 is manufactured by the steps described above.

Next, a method of manufacturing the second semiconductor laser 100 of Embodiment 5 will be described using an example. The steps up to FIG. 31 are the same as those in the method of manufacturing the second semiconductor laser 100 of Embodiment 4. Thereafter, as in the case of the second semiconductor laser 100 of Embodiment 4, the receded portion forming step of forming the receded portions 21 is performed. Next, the semi-insulating layer forming step of forming the semi-insulating layer 11 is performed. In the semi-insulating layer forming step, the second mask 33 is formed on the positive side of the protruding portion 18 in the z-direction as in FIG. 33. Using the second mask 33, the n-type diffusion block layer 16 and the semi-insulating layer 11 are sequentially formed in the region other than the positive side of the protruding portion 18 in the z-direction as in FIG. 40. The n-type diffusion block layer 16 and the semi-insulating layer 11 are formed by selective growth. More specifically, the semi-insulating layer 11 is formed on the side surface (the receded portion side surface 48) and the bottom portion 23 of the receded portion 21 on the positive side in the x-direction, and on the side surface (the receded portion side surface 48) and the bottom portion 23 of the receded portion 21 on the negative side in the x-direction via the n-type diffusion block layer 16. Thereafter, the second mask 33 is removed by using buffered hydrofluoric acid or hydrofluoric acid. Next, the insulating layer forming step as in the first or third semiconductor laser 100 of Embodiment 5 is performed to form the anode electrode 12 and the cathode electrode 13.

In the semiconductor laser 100 of Embodiment 5, the area of the n-type third buried layer 8 on the side of the second buried layer 7 can be reduced by the trenches 19 or the receded portions 21, and the area of the n-type third buried layer 8 on the side of the second buried layer 7 can be reduced also in the vicinity of the active layer 3. Therefore, the semiconductor laser 100 and the semiconductor laser device 200 of Embodiment 5 have the same effects as the semiconductor laser 100 and the semiconductor laser device 200 of Embodiment 4.

In the semiconductor laser 100 of Embodiment 4, the semi-insulating layer 11 covers those except for the positive side of the protruding portion 18 in the z-direction. However, when zinc or the like doped in the p-type second cladding layer 9 and the p-type contact layer 10 diffuses into the semi-insulating layer 11 doped with iron or the like, the semi-insulating property of the semi-insulating layer 11 is weakened, and the effect of blocking the leakage current by the semi-insulating layer 11 may be reduced. Therefore, in the semiconductor laser 100 of Embodiment 5, the n-type diffusion block layer 16 is formed, and the semi-insulating layer 11 is formed on the surface of the n-type diffusion block layer 16, so that zinc or the like doped in the p-type second cladding layer 9 and the p-type contact layer 10 can be prevented from diffusing into the buried layer 25. As a result, the semiconductor laser 100 of Embodiment 5 can reduce the parasitic capacitance of the buried layer 25 while the diffusion of zinc or the like causing the weakening in the semi-insulating property of the semi-insulating layer 11 is prevented, thereby efficiently injecting a current into the active layer 3 and improving heat dissipation of the heat generated in the active layer 3 as compared with the semiconductor laser 100 of Embodiment 4.

As described above, the first or third semiconductor laser 100 of Embodiment 5 includes the ridge 5 formed on the n-type semiconductor substrate 1 and the buried layer 25 buried so as to cover both sides of the ridge opposite to each other in the direction perpendicular to the extension direction of the ridge 5, and is a semiconductor laser mounted from the surface on the side where the ridge 5 protrudes. The z-direction, the y-direction, and the x-direction are as described above. The ridge 5 includes the n-type cladding layer 2, the active layer 3, and the p-type first cladding layer 4, which are sequentially formed from the side of the n-type semiconductor substrate 1. The buried layer 25 includes the p-type first buried layer 6 that is in contact with the side surface of the ridge 5 on the positive side in the x-direction and the side surface of the ridge 5 on the negative side in the x-direction, the second buried layer 7, and the n-type third buried layer 8. The semiconductor laser 100 includes the p-type second cladding layer 9, the p-type contact layer 10, which are sequentially formed on the positive side of the ridge 5 in the z-direction and on the positive side of the n-type third buried layer 8 in the z-direction in this order from the side of the n-type semiconductor substrate 1, the front surface-side electrode (anode electrode 12) connected to the p-type contact layer 10, and the semi-insulating layer 11, the semi-insulating layer 11 being formed on the outer edges separated in the x-direction from the ridge portion 50 including the ridge 5 and the p-type first buried layer 6 in contact with two side surfaces of the ridge 5. The semi-insulating layer 11 is formed on the positive side in the z-direction on the sides of the x-direction ends (x-direction ends 29a and 29b) in the semiconductor laser 100. Between the side surface of the ridge portion 50 on the positive side in the x-direction and the end on the positive side in the x-direction in the semiconductor laser 100 (x-direction end 29b), and between the side surface of the ridge portion 50 on the negative side in the x-direction and the end on the negative side in the x-direction in the semiconductor laser 100 (x-direction end 29a), the trenches 19 are formed to extend in the y-direction. Each of the trenches 19 penetrates the p-type contact layer 10, and the bottom portions 22 of the trenches 19 are disposed at any position in the z-direction between the p-type second cladding layer 9 and the inside of the n-type semiconductor substrate 1. The front surface-side electrode (anode electrode 12) is connected to the p-type contact layer 10 in the protruding portion 18 formed between the two trenches 19. The semi-insulating layer 11 is formed on the inner surfaces of the trenches 19 and on the positive side of the p-type contact layer 10 in the z-direction from the trench first side surfaces 46 of the trenches 19 to the x-direction ends (x-direction end 29a, 29b) opposite to the protruding portion 18 of the semiconductor laser 100 via the n-type diffusion block layer. With this configuration, the first or the third semiconductor laser 100 of Embodiment 5 includes the semi-insulating layer 11 that is separated in the x-direction from the ridge portion 50 having the active layer 3 and is at the outer edges on the side opposite to the n-type semiconductor substrate 1. Therefore, when the semiconductor laser 100 is mounted from the side of the front surface-side electrode (anode electrode 12), excellent heat dissipation can be achieved while the leakage current that does not contribute to the laser oscillation is suppressed.

The third semiconductor laser 100 of Embodiment 5 includes the ridge 5 formed on the n-type semiconductor substrate 1 and the buried layer 25 buried so as to cover both sides of the ridge opposite to each other in the direction perpendicular to the extension direction of the ridge 5, and is a semiconductor laser mounted from the surface on the side where the ridge 5 protrudes. The ridge 5 includes the n-type cladding layer 2, the active layer 3, and the p-type first cladding layer 4, which are sequentially formed from the side of the n-type semiconductor substrate 1. The buried layer 25 includes the p-type first buried layer 6 that is in contact with the side surface of the ridge 5 on the positive side in the x-direction and the side surface of the ridge 5 on the negative side in the x-direction, the second buried layer 7, and the n-type third buried layer 8. The semiconductor laser 100 includes the p-type second cladding layer 9, the p-type contact layer 10, which are sequentially formed on the positive side of the ridge 5 in the z-direction and on the positive side of the n-type third buried layer 8 in the z-direction in this order from the side of the n-type semiconductor substrate 1, the front surface-side electrode (anode electrode 12) connected to the p-type contact layer 10, and the semi-insulating layer 11, the semi-insulating layer 11 being formed on the outer edges separated in the x-direction from the ridge portion 50 including the ridge 5 and the p-type first buried layer 6 in contact with two side surfaces of the ridge 5. The semi-insulating layer 11 is formed on the positive side in the z-direction on the sides of the x-direction ends (x-direction ends 29a and 29b) in the semiconductor laser 100. The receded portions 21 formed to extend the y-direction are provided between the side surface of the ridge portion 50 on the positive side in the x-direction and the end on the positive side in the x-direction in the semiconductor laser 100 (x-direction end 29b) and between the side surface of the ridge portion 50 on the negative side in the x-direction and the end on the negative side in the x-direction in the semiconductor laser 100 (x-direction end 29a). In each of the receded portions 21, the p-type contact layer 10 is removed, and the bottom portions 23 of the receded portions 21 are disposed at any position in the z-direction between the p-type second cladding layer 9 and the inside of the n-type semiconductor substrate 1. The front surface-side electrode (anode electrode 12) is connected to the p-type contact layer 10 in the protruding portion 18 formed between the two receded portions 21. The semi-insulating layer 11 is formed on the side surface (receded portion side surface 48) and the bottom portion 23 in the receded portion 21 on the positive side in the x-direction, and on the side surface (receded portion side surface 48) and the bottom portion 23 in the receded portion on the negative side in the x-direction via the n-type diffusion block layer 16. With this configuration, the third semiconductor laser 100 of Embodiment 5 includes the semi-insulating layer 11 that is separated in the x-direction from the ridge portion 50 having the active layer 3 and is at the outer edges on the side opposite to the n-type semiconductor substrate 1. Therefore, when the semiconductor laser 100 is mounted from the side of the front surface-side electrode (anode electrode 12), excellent heat dissipation can be achieved while the leakage current that does not contribute to the laser oscillation is suppressed.

The semiconductor laser production method of Embodiment 5 is a semiconductor laser production method of manufacturing the semiconductor laser 100 including the ridge 5 formed on the n-type semiconductor substrate 1 and the buried layer 25 buried so as to cover both sides of the ridge opposite to each other in the direction perpendicular to the extension direction of the ridge 5. The semiconductor laser production method of Embodiment 5 includes the ridge forming step, the burying step, the stacking step, the trench forming step, the semi-insulating layer forming step, and the front surface-side electrode forming step, which will be described below In the ridge forming step, the n-type cladding layer 2, the active layer 3, and the p-type first cladding layer 4 are sequentially formed on the n-type semiconductor substrate 1, and then by the etching down to a position lower than the negative side of the active layer 3 in the z-direction, which is on the side of the n-type semiconductor substrate 1, the ridge 5 that includes the n-type cladding layer 2, the active layer 3, and the p-type first cladding layer 4 and in which the side surface on the positive side in the x-direction and the side surface on the negative side in the x-direction are exposed is formed. In the burying step, the p-type first buried layer 6 is formed on the side surface on the positive side in the x-direction and the side surface on the negative side in the x-direction in the ridge 5, and the ridge 5 is buried by the second buried layer 7 and the n-type third buried layer 8 that are sequentially formed to the position higher than the active layer surface position 44 that is a positive side position of the active layer in the z-direction. In the stacking step, the p-type second cladding layer 9 and the p-type contact layer 10 are sequentially formed on the positive side of the ridge 5 in the z-direction and on the positive side of the n-type third buried layer 8 in the z-direction. In the trench forming step, the p-type contact layer 10 is etched at two outer edges separated on the positive side and the negative side in the x-direction from the ridge portion 50 including the ridge 5 and the p-type first buried layer 6 in contact with two side surfaces of the ridge 5, and the trenches 19 are formed by the etching such that the position of the bottom portions 22 in the z-direction is to be any position in the z-direction between the p-type second cladding layer 9 and the inside of the n-type semiconductor substrate 1. In the semi-insulating layer forming step, the semi-insulating layer 11 is formed on the positive side of the p-type contact layer 10 in the z-direction on the sides that are separated in the x-direction from the protruding portion 18 formed between the two trenches 19 and are outside the trenches 19, and on the inner surfaces of the two trenches 19 via the n-type diffusion block layer 16. In the front surface-side electrode forming step, the front surface-side electrode (anode electrode 12) is formed so as to cover the p-type contact layer 10 on which the semi-insulating layer 11 of the protruding portion 18 is not formed in the semi-insulating layer forming step. With this configuration, the semiconductor laser production method of Embodiment 5 can manufacture the semiconductor laser 100 including the semi-insulating layer 11 that is separated in the x-direction from the ridge portion 50 having the active layer 3 and is at the outer edges on the side opposite to the n-type semiconductor substrate 1, so that excellent heat dissipation can be achieved while the leakage current not contributing to laser oscillation is suppressed when the semiconductor laser 100 is mounted from the side of the front surface-side electrode (anode electrode 12).

The other semiconductor laser production method of Embodiment 5 is a semiconductor laser production method of manufacturing the semiconductor laser 100 including the ridge 5 formed on the n-type semiconductor substrate 1 and the buried layer 25 buried so as to cover both sides of the ridge opposite to each other in the direction perpendicular to the extension direction of the ridge 5. The other semiconductor laser production method of Embodiment 5 includes the ridge forming step, the burying step, the stacking step, the receded portion forming step, the semi-insulating layer forming step, and the front surface-side electrode forming step, which will be described below. In the ridge forming step, the n-type cladding layer 2, the active layer 3, and the p-type first cladding layer 4 are sequentially formed on the n-type semiconductor substrate 1, and then by the etching down to a position lower than the negative side of the active layer 3 in the z-direction, which is on the side of the n-type semiconductor substrate 1, the ridge 5 that includes the n-type cladding layer 2, the active layer 3, and the p-type first cladding layer 4 and in which the side surface on the positive side in the x-direction and the side surface on the negative side in the x-direction are exposed is formed. In the burying step, the p-type first buried layer 6 is formed on the side surface on the positive side in the x-direction and the side surface on the negative side in the x-direction in the ridge 5, and the ridge 5 is buried by the second buried layer 7 and the n-type third buried layer 8 that are sequentially formed to the position higher than the active layer surface position 44 that is a positive side position of the active layer in the z-direction. In the stacking step, the p-type second cladding layer 9 and the p-type contact layer 10 are sequentially formed on the positive side of the ridge 5 in the z-direction and on the positive side of the n-type third buried layer 8 in the z-direction. In the receded portion forming step, the p-type contact layer 10 is etched at two outer edges separated on the positive side and the negative side in the x-direction from the ridge portion 50 including the ridge 5 and the p-type first buried layer 6 in contact with two side surfaces of the ridge 5, and the receded portions 21 are formed by the etching down to the position of the bottom portions 23 in the z-direction to be any position in the z-direction between the p-type second cladding layer 9 and the inside of the n-type semiconductor substrate 1. In the semi-insulating layer forming step, the semi-insulating layer is formed on the side surface (the receded portion side surface 48) and the bottom portion 23 of the receded portion 21 on the positive side in the x-direction, and on the side surface (the receded portion side surface 48) and the bottom portion 23 of the receded portion 21 on the negative side in the x-direction via the n-type diffusion block layer 16. In the front surface-side electrode forming step, the front surface-side electrode (anode electrode 12) is formed so as to cover the p-type contact layer 10 on which the semi-insulating layer 11 of the protruding portion 18 is not formed in the semi-insulating layer forming step in the protruding portion 18 formed between the two receded portions 21. With this configuration, the other semiconductor laser production method of Embodiment 5 can manufacture the semiconductor laser 100 including the semi-insulating layer 11 that is separated in the x-direction from the ridge portion 50 having the active layer 3 and is at the outer edges on the side opposite to the n-type semiconductor substrate 1, so that excellent heat dissipation can be achieved while the leakage current not contributing to laser oscillation is suppressed when the semiconductor laser 100 is mounted from the side of the front surface-side electrode (anode electrode 12).

Note that, although various exemplary embodiments and examples are described in the present application, various features, aspects, and functions described in one or more embodiments are not inherent in a particular embodiment and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component in another embodiment are included.

### DESCRIPTION OF REFERENCE NUMERALS AND SIGNS

1: n-type semiconductor substrate, 2: n-type cladding layer, 3: active layer, 4: p-type first cladding layer, 5: ridge, 6: p-type first buried layer, 7: second buried layer, 8: n-type third buried layer, 9: p-type second cladding layer, 10: p-type contact layer, 11: semi-insulating layer, 12: anode electrode (front surface-side electrode), 14: connection member, 15: insulating film, 16: n-type diffusion block layer, 17: heat sink, 18: protruding portion, 19: trench, 21: receded portion, 22: bottom portion, 23: bottom portion, 25: buried layer, 29a, 29b: x-direction end, 44: active layer surface position, 46: trench first side surface, 47: trench second side surface, 48: receded portion side surface, 50: ridge portion, 100: semiconductor laser, 200: semiconductor laser device

1. A semiconductor laser comprising:
a ridge formed on an n-type semiconductor substrate; and
a buried layer buried so as to cover both sides opposite to each other in a direction perpendicular to an extension direction of the ridge, wherein
the semiconductor laser is mounted from a surface on a side where the ridge protrudes,
a z-direction is a direction to which the ridge protrudes from a front surface side of the n-type semiconductor substrate,
a y-direction is an extension direction in which the ridge extends,
a x-direction is a direction perpendicular to the z-direction and the y-direction,
the ridge includes an n-type cladding layer, an active layer, and a p-type first cladding layer that are sequentially formed from a side of the n-type semiconductor substrate,
the buried layer includes a p-type first buried layer in contact with a side surface of the ridge on a negative side in the x-direction and a side surface of the ridge on a positive side in the x-direction, a second buried layer, and an n-type third buried layer,
a p-type second cladding layer and a p-type contact layer that are sequentially formed from the side of the n-type semiconductor substrate on the positive side of the ridge in the z-direction and on the positive side of the n-type third buried layer in the z-direction, a front surface-side electrode connected to the p-type contact layer, and a semi-insulating layer formed in outer edges separated in the x-direction form a ridge portion including the ridge and the p-type first buried layer in contact with the two side surfaces of the ridge are included, and
the semi-insulating layer or the front surface-side electrode is formed on the positive side in the z-direction at sides toward x-direction ends in the semiconductor laser.

2. The semiconductor laser according to claim 1, wherein
between the side surface of the ridge portion on the positive side in the x-direction and an end on the positive side in the x-direction in the semiconductor laser and between the side surface of the ridge portion on the negative side in the x-direction and an end on the negative side in the x-direction in the semiconductor laser, respective trenches formed to extend in the y-direction are provided,
each of the trenches penetrates the p-type contact layer, the p-type second cladding layer, and the n-type third buried layer, and bottom portions of the trenches are at the same position as an active layer surface position that is a positive side position of the active layer in the z-direction in the second buried layer or the bottom portions of the trenches are more distant from the n-type semiconductor substrate than the active layer surface position in the second buried layer,
the front surface-side electrode is connected to the p-type contact layer in a protruding portion formed between the two trenches,
trench first side surfaces are side surfaces in the x-direction in the trenches on sides separated from the protruding portion and trench second side surfaces are side surfaces in the x-direction in the trenches on sides closer to the protruding portion than the trench first side surfaces in the trenches, and
the semi-insulating layer is formed on the positive side of the p-type contact layer in the z-direction from the trench first side surfaces of the trenches to ends in the x-direction opposite to the protruding portion of the semiconductor laser.

3. The semiconductor laser according to claim 2, wherein an insulating film is provided in inner surfaces of the trenches.

4. The semiconductor laser according to claim 2, wherein
an insulating film is provided on the trench first side surfaces and the trench second side surfaces in the trenches, and
the front surface-side electrode covers the insulating film on the trench first side surfaces, the trench second side surfaces, and the bottom portions of the trenches.

5. The semiconductor laser according to claim 1, wherein
between the side surface of the ridge portion on the positive side in the x-direction and an end on the positive side in the x-direction in the semiconductor laser and between the side surface of the ridge portion on the negative side in the x-direction and an end on the negative side in the x-direction in the semiconductor laser, respective trenches formed to extend in the y-direction are provided,
each of the trenches penetrates the p-type contact layer, and bottom portions of the trenches are disposed at any position in the z-direction between the p-type second cladding layer and an inside of the n-type semiconductor substrate,
the front surface-side electrode is connected to the p-type contact layer in a protruding portion formed between the two trenches,
trench first side surfaces are side surfaces in the x-direction in the trenches on sides separated from the protruding portion and trench second side surfaces are side surfaces in the x-direction in the trenches on sides closer to the protruding portion than the trench first side surfaces in the trenches, and
the semi-insulating layer is formed directly or via an n-type diffusion block layer on inner surfaces of the trenches and on the positive side of the p-type contact layer in the z-direction from the trench first side surfaces of the trenches to ends in the x-direction opposite to the protruding portion of the semiconductor laser.

6. The semiconductor laser according to claim 1, wherein
between the side surface of the ridge portion on the positive side in the x-direction and an end on the positive side in the x-direction in the semiconductor laser and between the side surface of the ridge portion on the negative side in the x-direction and an end on the negative side in the x-direction in the semiconductor laser, respective receded portions formed to extend in the y-direction are provided,
in each of the receded portions, the p-type contact layer is removed, and bottom portions of the receded portions are disposed at any position in the z-direction between the p-type second cladding layer and an inside of the n-type semiconductor substrate,
the front surface-side electrode is connected to the p-type contact layer in a protruding portion formed between the two receded portions, and
the semi-insulating layer is formed directly or via an n-type diffusion block layer on a side surface and the bottom portion of the receded portion on the positive side in the x-direction and on a side surface and the bottom portion of the receded portion on the negative side in the x-direction.

7. The semiconductor laser according to claim 1, wherein, on the positive side in the z-direction at the sides toward the x-direction ends in the semiconductor laser, the front surface-side electrode covers the positive side of the semi-insulating layer in the z-direction.

8. The semiconductor laser according to claim 2, wherein the semi-insulating layer is not covered with the front surface-side electrode at the sides toward the x-direction ends in the semiconductor laser.

9. A semiconductor laser device comprising:
the semiconductor laser according to claim 1; and
a heat sink, wherein
a positive side in the z-direction where the front surface-side electrode of the semiconductor laser is formed is connected to the heat sink with a connection member.

10. A semiconductor laser production method of manufacturing a semiconductor laser including a ridge formed on a n-type semiconductor substrate and a buried layer buried so as to cover both sides opposite to each other in a direction perpendicular to an extension direction of the ridge, the method comprising:
a ridge forming step in which an n-type cladding layer, an active layer, and a p-type first cladding layer are sequentially formed on the n-type semiconductor substrate and the ridge that includes the n-type cladding layer, the active layer, and the p-type first cladding layer and in which a side surface on a positive side in an x-direction and a side surface on a negative side in the x-direction are exposed is formed by etching down to a position lower than the negative side of the active layer in a z-direction being a side of the n-type semiconductor substrate;
a burying step in which a p-type first buried layer is formed on the side surface on the positive side in the x-direction and the side surface on the negative side in the x-direction in the ridge and the ridge is buried by a second buried layer and an n-type third buried layer that are sequentially formed to a position higher than an active layer surface position being a position on the positive side of the active layer in the z-direction;
a stacking step in which a p-type second cladding layer, a p-type contact layer and a semi-insulating layer are sequentially formed on the positive side of the ridge in the z-direction and on the positive side of the n-type third buried layer in the z-direction;
a contact layer exposing step in which the p-type contact layer is exposed by etching the semi-insulating layer in a region in the x-direction encompassing a ridge portion including the ridge and the p-type first buried layer in contact with the two side surfaces of the ridge; and
a front surface-side electrode forming step in which a front surface-side electrode is formed on the exposed p-type contact layer and the semi-insulating layer on the positive side in the z-direction and on the side surfaces thereof on a side of the ridge portion, wherein
the z-direction is a direction to which the ridge protrudes from a front surface side of the n-type semiconductor substrate,
the y-direction is an extension direction in which the ridge extends, and
the x-direction is a direction perpendicular to the z-direction and the y-direction.

11. A semiconductor laser production method of manufacturing a semiconductor laser including a ridge formed on a n-type semiconductor substrate and a buried layer buried so as to cover both sides opposite to each other in a direction perpendicular to an extension direction of the ridge, the method comprising:
a ridge forming step in which an n-type cladding layer, an active layer, and a p-type first cladding layer are sequentially formed on the n-type semiconductor substrate and the ridge that includes the n-type cladding layer, the active layer, and the p-type first cladding layer and in which a side surface on a positive side in an x-direction and a side surface on a negative side in the x-direction are exposed is formed by etching down to a position lower than the negative side of the active layer in a z-direction being a side of the n-type semiconductor substrate;
a burying step in which a p-type first buried layer is formed on the side surface on the positive side in the x-direction and the side surface on the negative side in the x-direction in the ridge and the ridge is buried by a second buried layer and an n-type third buried layer that are sequentially formed to a position higher than an active layer surface position being a position on the positive side of the active layer in the z-direction;
a stacking step in which a p-type second cladding layer, a p-type contact layer and a semi-insulating layer are sequentially formed on the positive side of the ridge in the z-direction and on the positive side of the n-type third buried layer in the z-direction;
a trench forming step in which trenches are formed to penetrate the semi-insulating layer, the p-type contact layer, the p-type second cladding layer, and the n-type third buried layer at two outer edges separated on the positive side and the negative side in the x-direction from a ridge portion including the ridge and the p-type first buried layer in contact with the two side surfaces of the ridge, and the trenches are formed such that a position of bottom portions thereof in the z-direction is the same as the active layer surface position of the active layer in the second buried layer or the bottom portions are positioned on the positive side from the active layer surface position;
a contact layer exposing step in which the semi-insulating layer formed on a protruding portion between the two trenches is etched to expose the p-type contact layer;
an insulating film forming step in which an insulating film is formed on both side surfaces in the x-direction in each of the trenches; and
a front surface-side electrode forming step in which a front surface-side electrode is formed so as to cover the p-type contact layer where the insulating film on the protruding portion is not formed in the insulating film forming step, wherein
the z-direction is a direction to which the ridge protrudes from a front surface side of the n-type semiconductor substrate,
the y-direction is an extension direction in which the ridge extends, and
the x-direction is a direction perpendicular to the z-direction and the y-direction.

12. The semiconductor laser production method according to claim 11, wherein the insulating film is formed on the bottom portion of each of the trenches.

13. The semiconductor laser production method according to claim 11, wherein the front surface-side electrode covers the insulating layer on both the side surfaces of the trenches and the bottom portions of the trenches.

14. A semiconductor laser production method of manufacturing a semiconductor laser including a ridge formed on a n-type semiconductor substrate and a buried layer buried so as to cover both sides opposite to each other in a direction perpendicular to an extension direction of the ridge, the method comprising:
a ridge forming step in which an n-type cladding layer, an active layer, and a p-type first cladding layer are sequentially formed on the n-type semiconductor substrate and the ridge that includes the n-type cladding layer, the active layer, and the p-type first cladding layer and in which a side surface on a positive side in an x-direction and a side surface on a negative side in the x-direction are exposed is formed by etching down to a position lower than the negative side of the active layer in a z-direction being a side of the n-type semiconductor substrate;
a burying step in which a p-type first buried layer is formed on the side surface on the positive side in the x-direction and the side surface on the negative side in the x-direction in the ridge and the ridge is buried by a second buried layer and an n-type third buried layer that are sequentially formed to a position higher than an active layer surface position being a position on the positive side of the active layer in the z-direction;
a stacking step in which a p-type second cladding layer, and a p-type contact layer are sequentially formed on the positive side of the ridge in the z-direction and on the positive side of the n-type third buried layer in the z-direction;
a trench forming step in which the p-type contact layer is etched at two outer edges separated on the positive side and the negative side in the x-direction from a ridge portion including the ridge and the p-type first buried layer in contact with the two side surfaces of the ridge, and trenches are formed by etching such that a position of bottom portions thereof in the z-direction is to be any position in the z-direction between the p-type second cladding layer and an inside of the n-type semiconductor substrate;
a semi-insulating layer forming step in which a semi-insulating layer is formed directly or via an n-type diffusion block layer on the positive side of the p-type contact layer in the z-direction on sides that are separated in the x-direction from a protruding portion formed between the two trenches and are outside the trenches, and on inner surfaces of the two trenches;
a front surface-side electrode forming step in which a front surface-side electrode is formed so as to cover the p-type contact layer on which the semi-insulating layer of the protruding portion is not formed in the semi-insulating layer forming step, wherein
the z-direction is a direction to which the ridge protrudes from a front surface side of the n-type semiconductor substrate,
the y-direction is an extension direction in which the ridge extends, and
the x-direction is a direction perpendicular to the z-direction and the y-direction.

15. A semiconductor laser production method of manufacturing a semiconductor laser including a ridge formed on a n-type semiconductor substrate and a buried layer buried so as to cover both sides opposite to each other in a direction perpendicular to an extension direction of the ridge, the method comprising:
a ridge forming step in which an n-type cladding layer, an active layer, and a p-type first cladding layer are sequentially formed on the n-type semiconductor substrate and the ridge that includes the n-type cladding layer, the active layer, and the p-type first cladding layer and in which a side surface on a positive side in an x-direction and a side surface on a negative side in the x-direction are exposed is formed by etching down to a position lower than the negative side of the active layer in a z-direction being a side of the n-type semiconductor substrate;
a burying step in which a p-type first buried layer is formed on the side surface on the positive side in the x-direction and the side surface on the negative side in the x-direction in the ridge and the ridge is buried by a second buried layer and an n-type third buried layer that are sequentially formed to a position higher than an active layer surface position being a position on the positive side of the active layer in the z-direction;
a stacking step in which a p-type second cladding layer, and a p-type contact layer are sequentially formed on the positive side of the ridge in the z-direction and on the positive side of the n-type third buried layer in the z-direction;
a receded portion forming step in which the p-type contact layer is etched at two outer edges separated on the positive side and the negative side in the x-direction from a ridge portion including the ridge and the p-type first buried layer in contact with the two side surfaces of the ridge, and receded portions are formed by etching such that a position of bottom portions thereof in the z-direction is to be any position in the z-direction between the p-type second cladding layer and an inside of the n-type semiconductor substrate;
a semi-insulating layer forming step in which a semi-insulating layer is formed directly or via an n-type diffusion block layer on a side surface and the bottom portion of the receded portion on the positive side in the x-direction and on a side surface and the bottom portion of the receded portion on the negative side in the x-direction; and
a front surface-side electrode forming step in which a front surface-side electrode is formed so as to cover the p-type contact layer on which the semi-insulating layer of a protruding portion is not formed in the semi-insulating layer forming step in the protruding portion formed between the two receded portions, wherein
the z-direction is a direction to which the ridge protrudes from a front surface side of the n-type semiconductor substrate;
the y-direction is an extension direction in which the ridge extends;
the x-direction is a direction perpendicular to the z-direction and the y-direction.

16. The semiconductor laser according to claim 3, wherein the semi-insulating layer is not covered with the front surface-side electrode at the sides toward the x-direction ends in the semiconductor laser.

17. The semiconductor laser according to claim 4, wherein the semi-insulating layer is not covered with the front surface-side electrode at the sides toward the x-direction ends in the semiconductor laser.

18. A semiconductor laser device comprising:
the semiconductor laser according to claim 2; and
a heat sink, wherein
a positive side in the z-direction where the front surface-side electrode of the semiconductor laser is formed is connected to the heat sink with a connection member.

19. A semiconductor laser device comprising:
the semiconductor laser according to claim 3; and
a heat sink, wherein
a positive side in the z-direction where the front surface-side electrode of the semiconductor laser is formed is connected to the heat sink with a connection member.

20. A semiconductor laser device comprising:
the semiconductor laser according to claim 4; and
a heat sink, wherein
a positive side in the z-direction where the front surface-side electrode of the semiconductor laser is formed is connected to the heat sink with a connection member.
